(19) United States
(12) Patent Application Publication
(10) Pub. No.: US 2023/0397497 A1
(43) Pub. Date: Dec. 7, 2023

(54) NIR-ABSORBING MATERIALS FOR OPTOELECTRONIC APPLICATIONS

(71) Applicant: The University of Southern California, Los Angeles, CA (US)

(72) Inventors: Mark E. Thompson, Anaheim, CA (US); Konstantin Mallon, Los Angeles, CA (US)

(21) Appl. No.: 18/322,243

(22) Filed: May 23, 2023

Related U.S. Application Data
(60) Provisional application No. 63/347,688, filed on Jun. 1, 2022.

(51) Int. Cl. H10K 85/60; C09K 11/06; C07F 5/02; C07F 15/00; H10K 85/30; H10K 30/50

(52) U.S. Cl. CPC H10K 85/658; C09K 11/06; C07F 5/027; C07F 15/0033; H10K 85/342; H10K 30/50; C09K 2211/185; C09K 2211/1029; C09K 2211/1044; C09K 2211/1007; C09K 2211/1096

(57) ABSTRACT

Provided are compounds of Formula I and Formula II. Also provided are formulations comprising these compounds. Further provided are optoelectronic devices that utilize these compounds.

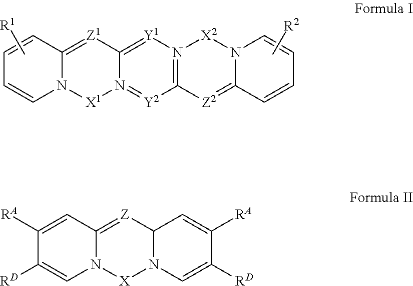

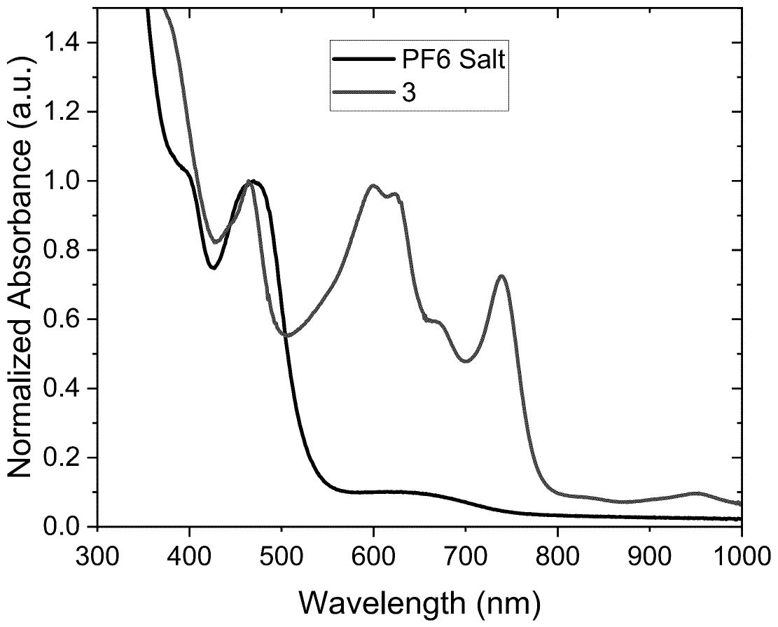

### CROSS-REFERENCE TO RELATED APPLICATIONS

The present application claims priority to U.S. Provisional Application No. 63/347,688, filed Jun. 1, 2022, which is incorporated by reference herein in its entirety.

### BACKGROUND

Optoelectronic devices rely on the optical and electronic properties of materials to either produce or detect electromagnetic radiation electronically or to generate electricity from ambient electromagnetic radiation. Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors.

Photosensitive optoelectronic devices convert electromagnetic radiation into electricity. Solar cells, also called photovoltaic (PV) devices or cells, are a type of photosensitive optoelectronic device that is specifically used to generate electrical power. PV devices, which may generate electrical energy from light sources other than sunlight, may be used to drive power consuming loads to provide, for example, lighting, heating, or to power electronic circuitry or devices such as calculators, radios, computers or remote monitoring or communications equipment. These power generation applications may involve the charging of batteries or other energy storage devices so that operation may continue when direct illumination from the sun or other light sources is not available, or to balance the power output of the PV device with the specific applications requirements.

Traditionally, photosensitive optoelectronic devices have been constructed of a number of inorganic semiconductors, e.g., crystalline, polycrystalline and amorphous silicon, gallium arsenide, cadmium telluride, and others.

More recent efforts have focused on the use of organic photovoltaic (OPV) cells to achieve acceptable photovoltaic conversion efficiencies with economical production costs. OPVs offer a low-cost, light-weight, and mechanically flexible route to solar energy conversion. Compared with polymers, small molecule OPVs share the advantage of using materials with well-defined molecular structures and weights. This leads to a reliable pathway for purification and the ability to deposit multiple layers using highly controlled thermal deposition without concern for dissolving, and thus damaging, previously deposited layers or subcells.

In addition to the pursuit of high device efficiency, OPVs have unique advantages, such as the application of semi-transparent solar cells for use in building integrated photovoltaics (BIPV). Considering the vast surface areas of windows and facades in modern urban environments, developing semi-transparent solar cells with both high efficiency and transmittance has become increasingly important. For a solar cell to be highly transparent, visible light would have to travel uninhibited to the eye, and hence cannot be absorbed. Selectively harvesting near-infrared (NIR) radiation avoids competition between efficiency and transmittance. However, the lack of high performance NIR absorbers in conventional fullerene based OPVs has prevented the attainment of efficient, yet highly transparent (in the visible) devices. To date, semi-transparent OPVs based on fullerene acceptors show only PCE less than or equal to 4% with average visible transmittance of 61%.

### SUMMARY OF THE INVENTION

In one aspect, the present invention relates to a compound of Formula I:

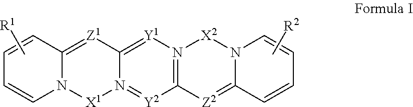

wherein:
X¹, and X² are each independently selected from the group consisting of B(R^{a})₂ and MLₙ;
M is a diamagnetic monovalent, divalent, or trivalent metal center, wherein the metal is a transition metal or a main group metal;
L is a monoanionic ligand; and
n+1 is the oxidation state of the metal;
Y¹ and Y² are each selected from the group consisting of CR³ and N;
Z¹ and Z² are each selected from the group consisting of CR⁴ and N;
R^{a} is selected from the group consisting of halide, alkoxide, alkyl, aryl, nitrile, and combinations thereof;
R¹ and R² each represent mono to the maximum allowable substitution, or no substitution;
each R¹, R², R³, and R⁴, are independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cyano, cycloalkenyl, heteroalkenyl, alkynyl, aryl, heteroaryl, acyl, carboxylic acid, ether, ester, nitro, nitrile, isonitrile, sulfanyl, sulfinyl, sulfonyl, phosphino, and combinations thereof;
any two R¹, R², R³, R⁴, and R^{a} can optionally join to form a carbocyclic ring or a heterocyclic ring, which is optionally substituted.

In another aspect, the present invention relates to a compound of Formula II:

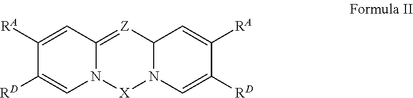

wherein
X is selected from the group consisting of B(R^{a})₂ and MLₙ;
M is a diamagnetic monovalent, divalent, or trivalent metal center, wherein the metal is a transition metal or a main group metal;
L is a monoanionic ligand; and
n+1 is the oxidation state of the metal;
R^{a} is selected from the group consisting of halide, alkoxide, alkyl, aryl, nitrile, and combinations thereof;
Z is selected from the group consisting of CR and N;
each R^{A} is independently an electron-accepting group selected from the group consisting of halogen, nitrile, heteroaryl, and nitro;
each R^{D} is independently an electron-donating group selected from the group consisting of dialkylamino, diarylamino, alkylarylamino, cycloalkylamino, alkyl, aryl, alkoxy, thioalkyl, halogen, and combinations thereof;
R is hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cyano, cycloalkenyl, heteroalkenyl, alkynyl, aryl, heteroaryl, acyl, carboxylic acid, ether, ester, nitro, nitrile, isonitrile, sulfanyl, sulfinyl, sulfonyl, phosphino, and combinations thereof.

In another aspect, the present disclosure provides a formulation comprising a compound of Formula I or Formula II as described herein.

In yet another aspect, the present disclosure provides an optoelectronic device comprising a compound of Formula I or Formula II as described herein.

### BRIEF DESCRIPTION OF THE DRAWINGS

The FIGURE shows the absorption spectra of Ir complex 3 and its cationic PF₆ salt in dichloromethane.

### DETAILED DESCRIPTION

The present disclosure relates in part to organic materials that have strong absorbance in the near infrared (NIR) part of the electromagnetic spectrum.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of optoelectronic devices are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, the terms “electrode” and “contact” may refer to a layer that provides a medium for delivering current to an external circuit or providing a bias current or voltage to the device. For example, an electrode, or contact, may provide the interface between the active regions of an organic photosensitive optoelectronic device and a wire, lead, trace or other means for transporting the charge carriers to or from the external circuit. Examples of electrodes include anodes and cathodes, which may be used in a photosensitive optoelectronic device.

As used herein, the term “transparent” may refer to a material that permits at least 50% of the incident electromagnetic radiation in relevant wavelengths to be transmitted through it. In a photosensitive optoelectronic device, it may be desirable to allow the maximum amount of ambient electromagnetic radiation from the device exterior to be admitted to the photoconductive active interior region. That is, the electromagnetic radiation must reach a photoconductive layer(s), where it can be converted to electricity by photoconductive absorption. This often dictates that at least one of the electrical contacts or electrodes should be minimally absorbing and minimally reflecting of the incident electromagnetic radiation. In some cases, such a contact should be transparent or at least semi-transparent. In one embodiment, the transparent material may form at least part of an electrical contact or electrode.

As used herein, the term “semi-transparent” may refer to a material that permits some, but less than 50% transmission of ambient electromagnetic radiation in relevant wavelengths. Where a transparent or semi-transparent electrode is used, the opposing electrode may be a reflective material so that light which has passed through the cell without being absorbed is reflected back through the cell.

As used and depicted herein, a “layer” refers to a member or component of a device, for example an optoelectronic device, being principally defined by a thickness, for example in relation to other neighboring layers, and extending outward in length and width. It should be understood that the term “layer” is not necessarily limited to single layers or sheets of materials. In addition, it should be understood that the surfaces of certain layers, including the interface(s) of such layers with other material(s) or layers(s), may be imperfect, wherein said surfaces represent an interpenetrating, entangled or convoluted network with other material(s) or layer(s). Similarly, it should also be understood that a layer may be discontinuous, such that the continuity of said layer along the length and width may be disturbed or otherwise interrupted by other layer(s) or material(s).

As used herein, a “photoactive region” refers to a region of a device that absorbs electromagnetic radiation to generate excitons. Similarly, a layer is “photoactive” if it absorbs electromagnetic radiation to generate excitons. The excitons may dissociate into an electron and a hole in order to generate an electrical current.

As used herein, the terms “donor” and “acceptor” refer to the relative positions of the highest occupied molecular orbital (“HOMO”) and lowest unoccupied molecular orbital (“LUMO”) energy levels of two contacting but different organic materials. If the LUMO energy level of one material in contact with another is lower, then that material is an acceptor. Otherwise it is a donor. It is energetically favorable, in the absence of an external bias, for electrons at a donor-acceptor junction to move into the acceptor material, and for holes to move into the donor material.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

As used herein, the term “band gap” (E_{g}) of a polymer may refer to the energy difference between the HOMO and the LUMO. The band gap is typically reported in electron volts (eV). The band gap may be measured from the UV-vis spectroscopy or cyclic voltammetry. A “low band gap” polymer may refer to a polymer with a band gap below 2 eV, e.g., the polymer absorbs light with wavelengths longer than 620 nm.

As used herein, the term “excitation binding energy” (E_{B}) may refer to the following formula: E_{B}=(M⁺+M⁻)−(M*+M), where M⁺ and M⁻ are the total energy of a positively and negatively charged molecule, respectively; M* and M are the molecular energy at the first singlet state (S₁) and ground state, respectively. Excitation binding energy of acceptor or donor molecules affects the energy offset needed for efficient exciton dissociation. In certain examples, the escape yield of a hole increases as the HOMO offset increases. A decrease of exciton binding energy E_{B} for the acceptor molecule leads to an increase of hole escape yield for the same HOMO offset between donor and acceptor molecules.

As used herein, “power conversion efficiency” (PCE) (η_{ρ}) may be expressed as:

$${η}_{ρ} = \frac{{V}_{OC} * FF * {J}_{SC}}{{P}_{O}}$$

wherein V_{OC} is the open circuit voltage, FF is the fill factor, J_{SC} is the short circuit current, and P_{O} is the input optical power.

As used herein, “spin coating” may refer to the process of solution depositing a layer or film of one material (i.e., the coating material) on a surface of an adjacent substrate or layer of material. The spin coating process may include applying a small amount of the coating material on the center of the substrate, which is either spinning at low speed or not spinning at all. The substrate is then rotated at high speed in order to spread the coating material by centrifugal force. Rotation is continued while the fluid spins off the edges of the substrate, until the desired thickness of the film is achieved. The applied solvent is usually volatile, and simultaneously evaporates. Therefore, the higher the angular speed of spinning, the thinner the film. The thickness of the film also depends on the viscosity and concentration of the solution and the solvent.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

The terms “halo,” “halogen,” and “halide” are used interchangeably and refer to fluorine, chlorine, bromine, and iodine.

The term “pseudohalogen” refers to polyatomic analogues of halogens, whose chemistry, resembling that of the true halogens, allows them to substitute for halogens in several classes of chemical compounds. Exemplary pseudohalogens include, but are not limited to, nitrile, cyaphide, isocyanide, cyanate, isocyanate, fulminate, thiocyanate, isothiocyanate, selenocyanate, tellurocyanate, azide, tetracarbonylcobaltate, trinitromethanide, and tricyanomethanide groups.

The term “acyl” refers to a substituted carbonyl radical (C(O)—R_{S}).

The term “ester” refers to a substituted oxycarbonyl (—O—C(O)—R, or —C(O)—O—R_{S}) radical.

The term “ether” refers to an —OR_{S} radical.

The terms “sulfanyl” or “thio-ether” are used interchangeably and refer to a —SR_{S} radical.

The term “sulfinyl” refers to a —S(O)—R, radical.

The term “sulfonyl” refers to a —SO₂—R, radical.

The term “phosphino” refers to a —P(R_{S})₃ radical, wherein each R_{S} can be same or different.

The term “silyl” refers to a —Si(R_{S})₃ radical, wherein each R_{S} can be same or different.

The term “boryl” refers to a —B(R_{S})₂ radical or its Lewis adduct —B(R_{S})₃ radical, wherein Rs can be same or different.

In each of the above, R can be hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, and combination thereof Preferred R s is selected from the group consisting of alkyl, cycloalkyl, aryl, heteroaryl, and combination thereof.

The term “alkyl” refers to and includes both straight and branched chain alkyl radicals. Preferred alkyl groups are those containing from one to fifteen carbon atoms and includes methyl, ethyl, propyl, 1-methylethyl, butyl, 1-methylpropyl, 2-methylpropyl, pentyl, 1-methylbutyl, 2-methylbutyl, 3-methylbutyl, 1,1-dimethylpropyl, 1,2-dimethylpropyl, 2,2-dimethylpropyl, and the like. Additionally, the alkyl group is optionally substituted.

The term “cycloalkyl” refers to and includes monocyclic, polycyclic, and spiro alkyl radicals. Preferred cycloalkyl groups are those containing 3 to 12 ring carbon atoms and includes cyclopropyl, cyclopentyl, cyclohexyl, bicyclo[3.1.1]heptyl, spiro[4.5]decyl, spiro[5.5]undecyl, adamantyl, and the like. Additionally, the cycloalkyl group is optionally substituted.

The terms “heteroalkyl” or “heterocycloalkyl” refer to an alkyl or a cycloalkyl radical, respectively, having at least one carbon atom replaced by a heteroatom. Optionally the at least one heteroatom is selected from O, S, N, P, B, Si and Se, preferably, O, S or N. Additionally, the heteroalkyl or heterocycloalkyl group is optionally substituted.

The term “alkenyl” refers to and includes both straight and branched chain alkene radicals. Alkenyl groups are essentially alkyl groups that include at least one carbon-carbon double bond in the alkyl chain. Cycloalkenyl groups are essentially cycloalkyl groups that include at least one carbon-carbon double bond in the cycloalkyl ring. The term “heteroalkenyl” as used herein refers to an alkenyl radical having at least one carbon atom replaced by a heteroatom. Optionally the at least one heteroatom is selected from O, S, N, P, B, Si, and Se, preferably, O, S, or N. Preferred alkenyl, cycloalkenyl, or heteroalkenyl groups are those containing two to fifteen carbon atoms. Additionally, the alkenyl, cycloalkenyl, or heteroalkenyl group is optionally substituted.

The term “alkynyl” refers to and includes both straight and branched chain alkyne radicals. Preferred alkynyl groups are those containing two to fifteen carbon atoms. Additionally, the alkynyl group is optionally substituted.

The terms “aralkyl” or “arylalkyl” are used interchangeably and refer to an alkyl group that is substituted with an aryl group. Additionally, the aralkyl group is optionally substituted.

The term “heterocyclic group” refers to and includes aromatic and non-aromatic cyclic radicals containing at least one heteroatom. Optionally the at least one heteroatom is selected from O, S, N, P, B, Si, and Se, preferably, O, S, or N. Hetero-aromatic cyclic radicals may be used interchangeably with heteroaryl. Preferred hetero-non-aromatic cyclic groups are those containing 3 to 7 ring atoms which includes at least one hetero atom, and includes cyclic amines such as morpholino, piperidino, pyrrolidino, and the like, and cyclic ethers/thio-ethers, such as tetrahydrofuran, tetrahydropyran, tetrahydrothiophene, and the like. Additionally, the heterocyclic group may be optionally substituted.

The term “aryl” refers to and includes both single-ring aromatic hydrocarbyl groups and polycyclic aromatic ring systems. The polycyclic rings may have two or more rings in which two carbons are common to two adjoining rings (the rings are “fused”) wherein at least one of the rings is an aromatic hydrocarbyl group, e.g., the other rings can be cycloalkyls, cycloalkenyls, aryl, heterocycles, and/or heteroaryls. Preferred aryl groups are those containing six to thirty carbon atoms, preferably six to twenty carbon atoms, more preferably six to twelve carbon atoms. Especially preferred is an aryl group having six carbons, ten carbons or twelve carbons. Suitable aryl groups include phenyl, biphenyl, triphenyl, triphenylene, tetraphenylene, naphthalene, anthracene, phenalene, phenanthrene, fluorene, pyrene, chrysene, perylene, and azulene, preferably phenyl, biphenyl, triphenyl, triphenylene, fluorene, and naphthalene. Additionally, the aryl group is optionally substituted.

The term “heteroaryl” refers to and includes both single-ring aromatic groups and polycyclic aromatic ring systems that include at least one heteroatom. The heteroatoms include, but are not limited to O, S, N, P, B, Si, and Se. In many instances, O, S, or N are the preferred heteroatoms. Hetero-single ring aromatic systems are preferably single rings with 5 or 6 ring atoms, and the ring can have from one to six heteroatoms. The hetero-polycyclic ring systems can have two or more rings in which two atoms are common to two adjoining rings (the rings are “fused”) wherein at least one of the rings is a heteroaryl, e.g., the other rings can be cycloalkyls, cycloalkenyls, aryl, heterocycles, and/or heteroaryls. The hetero-polycyclic aromatic ring systems can have from one to six heteroatoms per ring of the polycyclic aromatic ring system. Preferred heteroaryl groups are those containing three to thirty carbon atoms, preferably three to twenty carbon atoms, more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group is optionally substituted.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, and benzimidazole, and the respective aza-analogs of each thereof are of particular interest.

The terms alkyl, cycloalkyl, heteroalkyl, heterocycloalkyl, alkenyl, cycloalkenyl, heteroalkenyl, alkynyl, aralkyl, heterocyclic group, aryl, and heteroaryl, as used herein, are independently unsubstituted, or independently substituted, with one or more general substituents.

In many instances, the general substituents are selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfanyl, sulfonyl, phosphino, and combinations thereof.

In some instances, the preferred general substituents are selected from the group consisting of deuterium, fluorine, alkyl, cycloalkyl, heteroalkyl, alkoxy, aryloxy, amino, silyl, alkenyl, cycloalkenyl, heteroalkenyl, aryl, heteroaryl, nitrile, isonitrile, sulfanyl, and combinations thereof

In some instances, the preferred general substituents are selected from the group consisting of deuterium, fluorine, alkyl, cycloalkyl, alkoxy, aryloxy, amino, silyl, aryl, heteroaryl, sulfanyl, and combinations thereof

In yet other instances, the more preferred general substituents are selected from the group consisting of deuterium, fluorine, alkyl, cycloalkyl, aryl, heteroaryl, and combinations thereof

The terms “substituted” and “substitution” refer to a substituent other than H that is bonded to the relevant position, e.g., a carbon or nitrogen. For example, when R¹ represents mono-substitution, then one R¹ must be other than H (i.e., a substitution). Similarly, when R¹ represents di-substitution, then two of R¹ must be other than H. Similarly, when R¹ represents no substitution, R¹, for example, can be a hydrogen for available valencies of ring atoms, as in carbon atoms for benzene and the nitrogen atom in pyrrole, or simply represents nothing for ring atoms with fully filled valencies, e.g., the nitrogen atom in pyridine. The maximum number of substitutions possible in a ring structure will depend on the total number of available valencies in the ring atoms.

As used herein, “combinations thereof” indicates that one or more members of the applicable list are combined to form a known or chemically stable arrangement that one of ordinary skill in the art can envision from the applicable list. For example, an alkyl and deuterium can be combined to form a partial or fully deuterated alkyl group; a halogen and alkyl can be combined to form a halogenated alkyl substituent; and a halogen, alkyl, and aryl can be combined to form a halogenated arylalkyl. In one instance, the term substitution includes a combination of two to four of the listed groups. In another instance, the term substitution includes a combination of two to three groups. In yet another instance, the term substitution includes a combination of two groups. Preferred combinations of substituent groups are those that contain up to fifty atoms that are not hydrogen or deuterium, or those which include up to forty atoms that are not hydrogen or deuterium, or those that include up to thirty atoms that are not hydrogen or deuterium. In many instances, a preferred combination of substituent groups will include up to twenty atoms that are not hydrogen or deuterium.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[f,h]quinoxaline and dibenzo[f,h]quinoline. One of ordinary skill in the art can readily envision other nitrogen analogs of the aza-derivatives described above, and all such analogs are intended to be encompassed by the terms as set forth herein.

As used herein, “deuterium” refers to an isotope of hydrogen. Deuterated compounds can be readily prepared using methods known in the art. For example, U.S. Pat. No. 8,557,400, Patent Pub. No. WO 2006/095951, and U.S. Pat. Application Pub. No. US 2011/0037057, which are hereby incorporated by reference in their entireties, describe the making of deuterium-substituted organometallic complexes. Further reference is made to Ming Yan, et al., Tetrahedron 2015, 71, 1425-30 and Atzrodt et al., Angew. Chem. Int. Ed. (Reviews) 2007, 46, 7744-65, which are incorporated by reference in their entireties, describe the deuteration of the methylene hydrogens in benzyl amines and efficient pathways to replace aromatic ring hydrogens with deuterium, respectively.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In some instance, a pair of adjacent substituents can be optionally joined or fused into a ring. The preferred ring is a five, six, or seven-membered carbocyclic or heterocyclic ring, includes both instances where the portion of the ring formed by the pair of substituents is saturated and where the portion of the ring formed by the pair of substituents is unsaturated. As used herein, “adjacent” means that the two substituents involved can be on the same ring next to each other, or on two neighboring rings having the two closest available substitutable positions, such as 2,2′ positions in a biphenyl, or 1,8 position in a naphthalene, as long as they can form a stable fused ring system.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and organic vapor jet printing (OVJP). Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processability than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention can be incorporated into a wide variety of electronic component modules (or units) that can be incorporated into a variety of electronic products or intermediate components.

The materials and structures described herein may have applications in devices other than organic solar cells. For example, other optoelectronic devices such as organic electroluminescent devices (OLEDs) and organic photodetectors may employ the materials and structures. More generally, organic devices, such as organic transistors, may employ the materials and structures.

In one aspect, the present disclosure relates to a compound represented by Formula I:

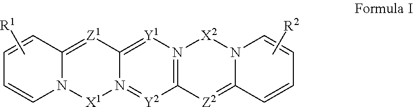

wherein:
X¹, and X² are each independently selected from the group consisting of B(R^{a})₂ and MLₙ;
M is a diamagnetic monovalent, divalent, or trivalent metal center, wherein the metal is a transition metal or a main group metal;
L is a monoanionic ligand; and
n+1 is the oxidation state of the metal;
Y¹ and Y² are each selected from the group consisting of CR³ and N;
Z¹ and Z² are each selected from the group consisting of CR⁴ and N;
R^{a} is selected from the group consisting of halide, alkoxide, alkyl, aryl, nitrile, and combinations thereof;
R¹ and R² each represent mono to the maximum allowable substitution, or no substitution; each R¹, R², R³, and R⁴, are independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cyano, cycloalkenyl, heteroalkenyl, alkynyl, aryl, heteroaryl, acyl, carboxylic acid, ether, ester, nitro, nitrile, isonitrile, sulfanyl, sulfinyl, sulfonyl, phosphino, and combinations thereof;
any two R¹, R², R³, R⁴, and R^{a} can optionally join to form a carbocyclic ring or a heterocyclic ring, which is optionally substituted.

In one embodiment, Y¹ and Y² are each N.

In one embodiment, Z¹ and Z² are each CR⁴. In one embodiment, R⁴ is nitrile.

In one embodiment, X¹ and X² are each B(Rₐ)₂. In one embodiment, R^{a} is nitrile, phenyl, or ethyl.

In one embodiment, one of X¹ and X² is B(Rₐ)₂ and the other of X¹ and X² is Ir(L)₂; wherein L represents a bidentate monoanionic ligand; and each L can be the same or different.

In one embodiment, X¹ and X² are both Ir(L)₂; L represents a bidentate monoanionic ligand; and each L can be the same or different.

In one embodiment, each L is independently selected from the group consisting of:

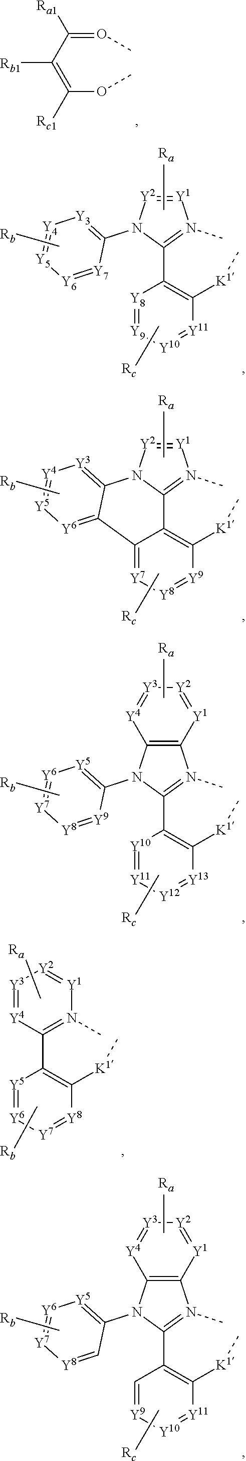

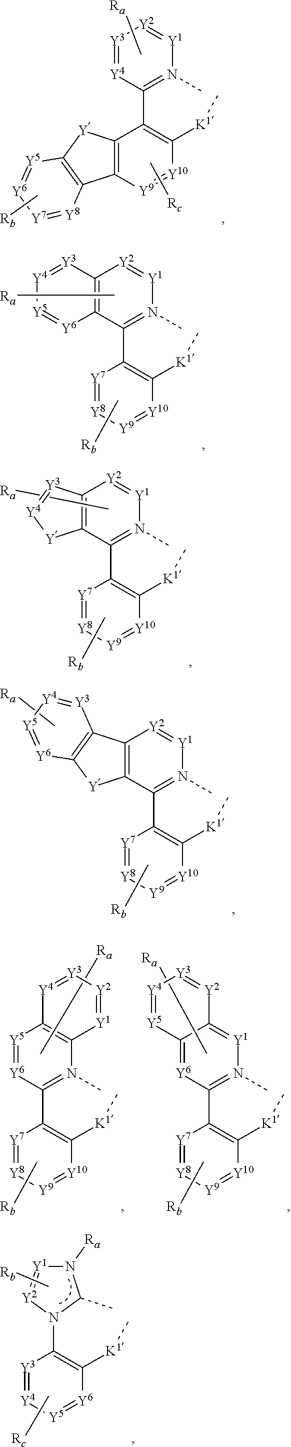

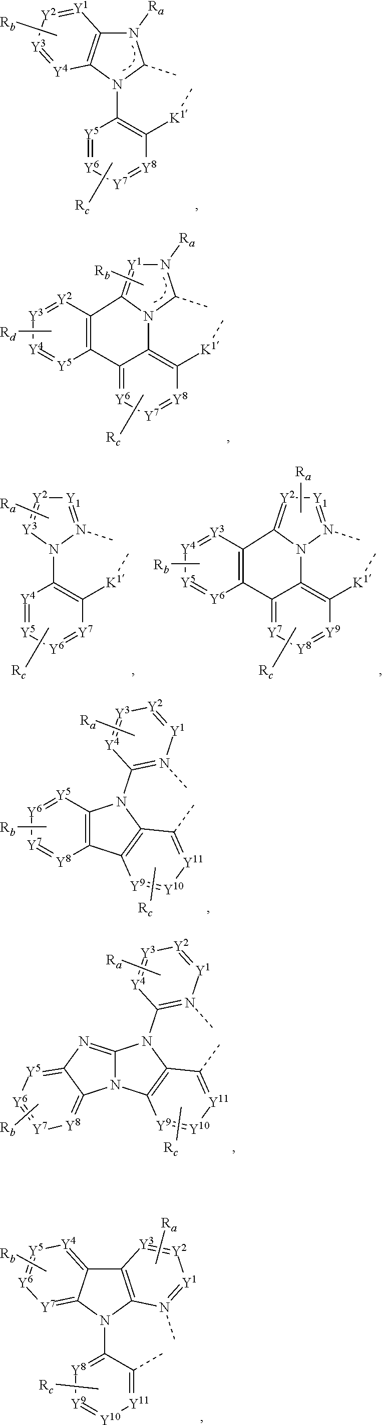

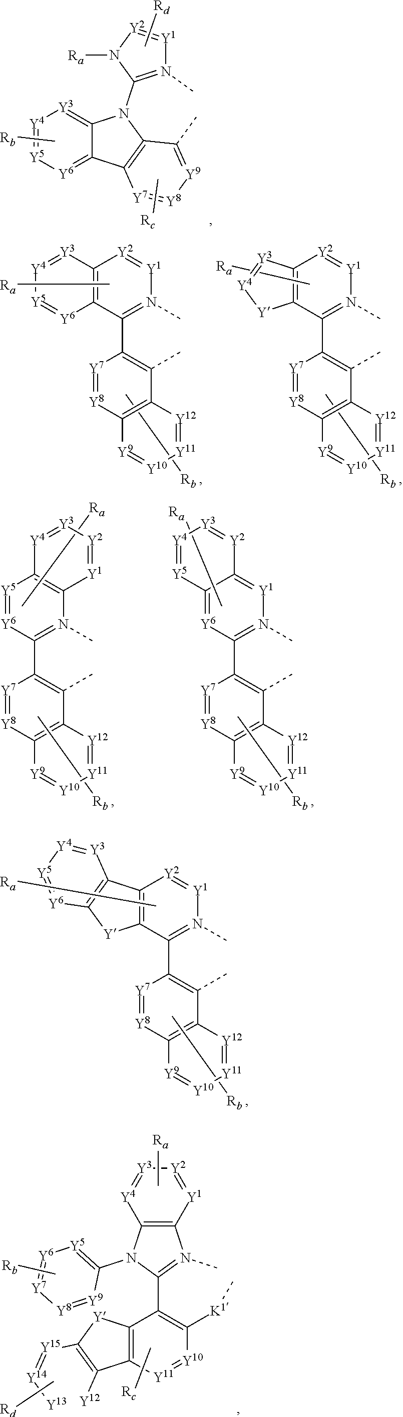

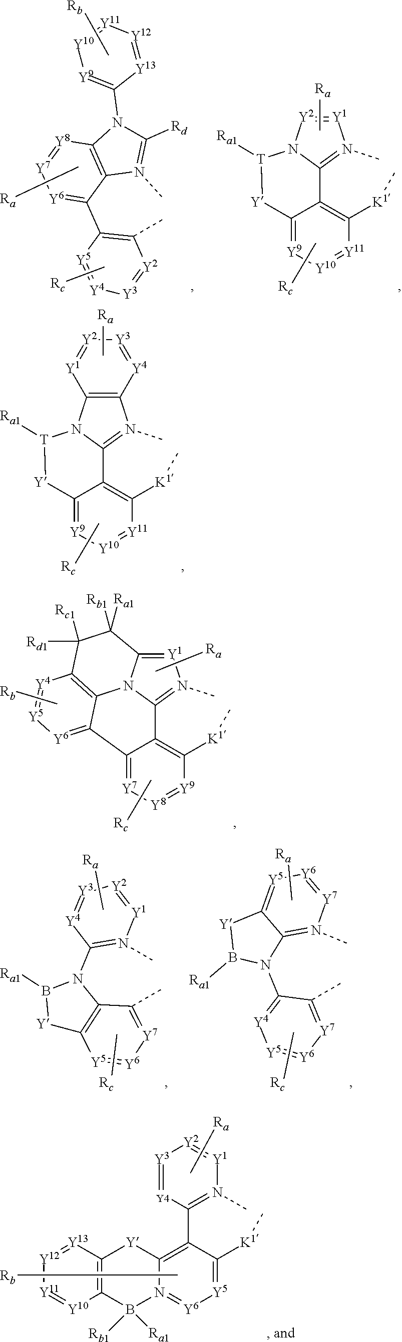

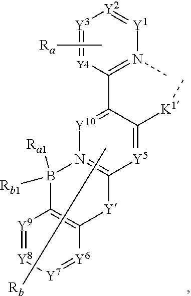

wherein:
T is selected from the group consisting of B, Al, Ga, and In;
K^{1′} is selected from the group consisting of a single bond, O, S, NRₑ, PRₑ, BRₑ, CRₑR_{f}, and SiRₑR_{f};
each of Y¹ to Y¹³ is independently selected from the group consisting of C and N;
Y′ is selected from the group consisting of BRₑ, BRₑR_{f}, NRₑ, PRₑ, P(O)Rₑ, O, S, Se, C═O, C═S, C═Se, C═NRₑ, C═CRₑR_{f}, S═O, SO₂, CRₑR_{f}, SiRₑR_{f}, and GeRₑR_{f};
Rₑ and R_{f} can be fused or joined to form a ring;
each Rₐ, R_{b}, R_{c}, and R_{d} independently represents from mono to the maximum allowed number of substitutions, or no substitution;
each of Rₐ₁, R_{b1}, R_{c1}, R_{d1}, Rₐ, R_{b}, R_{c}, R_{d}, Rₑ, and R_{f} is independently a hydrogen or a subsituent selected from the group consisting of deuterium, halide, alkyl, cycloalkyl, heteroalkyl, arylalkyl, alkoxy, aryloxy, amino, silyl, germyl, boryl, alkenyl, cycloalkenyl, heteroalkenyl, alkynyl, aryl, heteroaryl, acyl, carbonyl, carboxylic acid, ester, nitrile, isonitrile, sulfanyl, selenyl, sulfinyl, sulfonyl, phosphino, and combinations thereof; and
any two substituents of Rₐ₁, R_{b1}, R_{c1}, R_{d1}, Rₐ, R_{b}, R_{c}, and R_{d} can be fused or joined to form a ring or form a multidentate ligand.

In one embodiment, the compound is represented by one of the following structures:

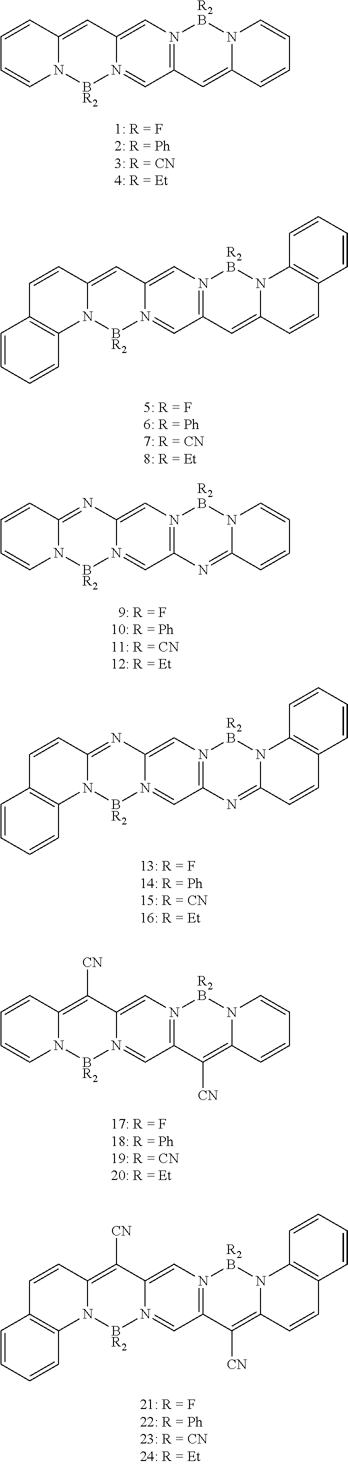

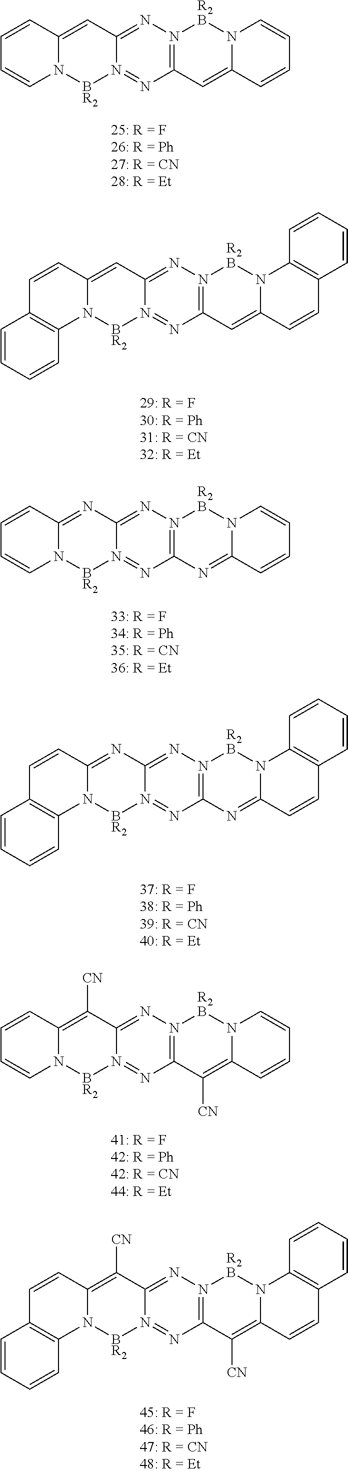

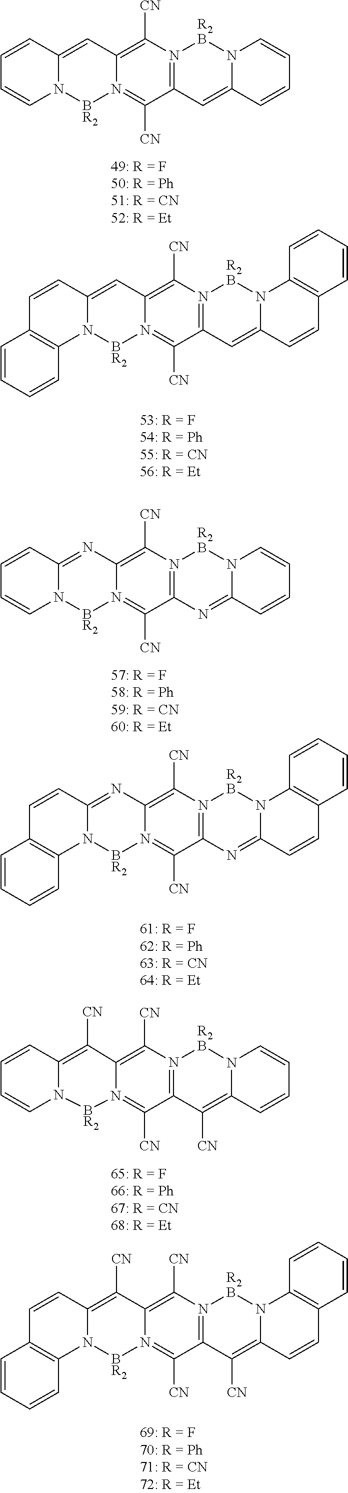

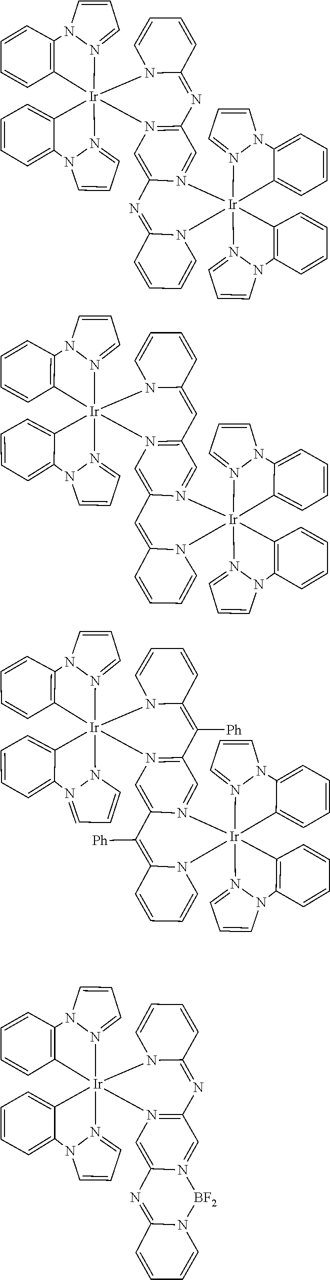

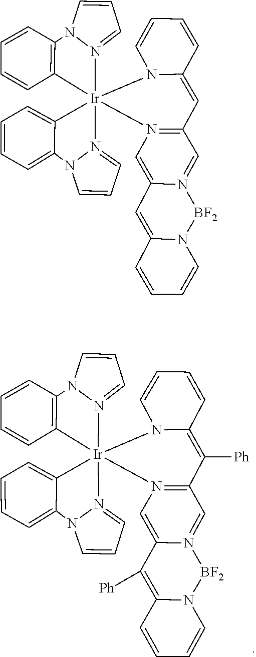

In another aspect, the present invention relates to a compound of Formula II:

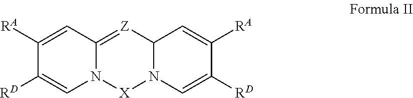

wherein
X is selected from the group consisting of B(R^{a})₂ and MLₙ;
M is a diamagnetic monovalent, divalent, or trivalent metal center, wherein the metal is a transition metal or a main group metal;
L is a monoanionic ligand; and
n+1 is the oxidation state of the metal;
R^{a} is selected from the group consisting of halide, alkoxide, alkyl, aryl, nitrile, and combinations thereof;
Z is selected from the group consisting of CR and N;
each R^{A} is independently an electron-accepting group selected from the group consisting of halogen, nitrile, heteroaryl, and nitro;
each R^{D} is independently an electron-donating group selected from the group consisting of dialkylamino, diarylamino, alkylarylamino, cycloalkylamino, alkyl, aryl, alkoxy, thioalkyl, halogen, and combinations thereof;
R is hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cyano, cycloalkenyl, heteroalkenyl, alkynyl, aryl, heteroaryl, acyl, carboxylic acid, ether, ester, nitro, nitrile, isonitrile, sulfanyl, sulfinyl, sulfonyl, phosphino, and combinations thereof.

In one embodiment, X is B(R^{a})₂.

In one embodiment, each R A represents nitro. In one embodiment, each R D represents dialkylamino or cycloalkylamino.

In one embodiment, the compound is represented by one of the following structures:

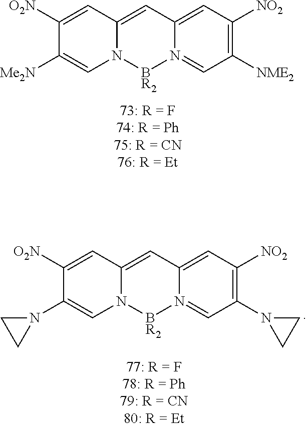

According to another aspect, a formulation comprising a compound described herein is also disclosed.

Organic Photovoltaic Cells

In one aspect, the invention relates to an OPV device comprising a compound of the disclosure. In one embodiment, the OPV device includes an anode; a cathode; and an active material positioned between the anode and cathode, wherein the active material comprises an acceptor and a donor.

In one embodiment, the OPV device comprises a single junction organic photovoltaic device. In one embodiment, the OPV device comprises two electrodes having an anode and a cathode in superposed relation, at least one donor composition, and at least one acceptor composition, wherein the donor-acceptor material or active layer is positioned between the two electrodes. In one embodiment, one or more intermediate layers may be positioned between the anode and the active layer. Additionally, or alternatively, one or more intermediate layers may be positioned between the active layer and cathode.

In one embodiment, the anode comprises a conducting oxide, thin metal layer, or conducting polymer. In one embodiment, the anode comprises a conductive metal oxide. Exemplary conductive metal oxides include, but are not limited to, indium tin oxide (ITO), tin oxide (TO), gallium indium tin oxide (GITO), zinc oxide (ZO), and zinc indium tin oxide (ZITO). In one embodiment, the anode comprises a metal layer. Exemplary metals for the metal layer include, but are not limited to, Ag, Au, Pd, Pt, Ti, V, Zn, Sn, Al, Co, Ni, Cu, Cr, and combinations thereof In one embodiment, the metal layer comprises a thin metal layer. In one embodiment, the anode 102 comprises a conductive polymer. Exemplary conductive polymers include, but are not limited to, polyanaline (PANI), or 3,4-polyethyl-enedioxythiophene:polystyrenesulfonate (PEDOT:PSS). In one embodiment, thickness of the anode is between about 0.1-100 nm. In one embodiment, thickness of the anode is between about 1-10 nm. In one embodiment, thickness of the anode is between about 0.1-10 nm. In one embodiment, thickness of the anode is between about 10-100 nm. In one embodiment, anode comprises a transparent or semi-transparent conductive material.

In one embodiment, the cathode comprises a conducting oxide, a metal layer, or conducting polymer. Exemplary conducting oxide, metal layers, and conducting polymers are described elsewhere herein. In one embodiment, the cathode comprises a thin metal layer. In one embodiment, the cathode comprises a metal or metal alloy. In one embodiment, the cathode may comprise Ca, Al, Mg, Ti, W, Ag, Au, or another appropriate metal, or an alloy thereof. In one embodiment, the thickness of the cathode is between about 0.1-100 nm. In one embodiment, the thickness of the cathode is between about 1-10 nm. In one embodiment, the thickness of the cathode is between about 0.1-10 nm. In one embodiment, the thickness of the cathode is between about 10-100 nm. In one embodiment, cathode comprises a transparent or semi-transparent conductive material.

In one embodiment, the OPV device may comprise one or more charge collecting/transporting intermediate layers positioned between an electrode and the active region or layer. In one embodiment, the OPV device comprises one or more intermediate layers. In one embodiment, the intermediate layer comprises a metal oxide. Exemplary metal oxides include, but are not limited to, MoO3, V2O5, ZnO, and TiO2. In one embodiment, the first intermediate layer has the same composition as the second intermediate layer. In one embodiment, the first intermediate layer and the second intermediate layer have different compositions. In one embodiment, the thickness of the intermediate layers are each independently between about 0.1-100 nm. In one embodiment, the thickness of the intermediate layers are each independently between about 1-10 nm. In one embodiment, the thickness of the intermediate layers are each independently between about 0.1-10 nm. In one embodiment, the thickness of the intermediate layers are each independently between about 10-100 nm.

In one embodiment, the OPV device comprises various layers of a tandem or multi junction photovoltaic device. In one embodiment, the OPV device comprises two electrodes having an anode and a 204 in superposed relation, at least one donor composition, and at least one acceptor composition positioned within a plurality of active layers or regions between the two electrodes. Additional active layers or regions are also possible. In one embodiment, the anode and the cathode each independently comprise a conducting oxide, thin metal layer, or conducting polymer. Exemplary conducting oxides, metal layers, and conducting polymers are described elsewhere herein.

In one embodiment, the OPV device comprises one or more intermediate layers positioned between the anode and a first active layer. Additionally, or alternatively, at least one intermediate layer may be positioned between the second active layer and cathode. In one embodiment, the OPV device comprises one or more intermediate layers positioned between the first active layer and the second active layer. In one embodiment, the OPV device comprises a first intermediate layer. In one embodiment, the OPV device comprises a second intermediate layer. In one embodiment, the OPV device comprises a third intermediate layer. In one embodiment, the OPV device comprises both first and second intermediate layers. In one embodiment, the OPV device comprises both first and third intermediate layers. In one embodiment, the OPV device comprises both second and third intermediate layers. In one embodiment, the OPV device comprises first, second, and third intermediate layers. In one embodiment, the first, second, and/or third intermediate layer comprises a metal oxide. Exemplary metal oxides are described elsewhere herein.

### Experimental Examples

It is understood that the various embodiments described herein are by way of example only, and are not intended to limit the scope of the disclosure. For example, many of the materials and structures described herein may be substituted with other materials and structures without deviating from the spirit of the disclosure. The present compounds as disclosed may therefore include variations from the particular examples and preferred embodiments described herein, as will be apparent to one of skill in the art. It is understood that various theories as to why the embodiments work are not intended to be limiting.

There is a great deal of need for organic materials that have strong absorbance in the near infrared (NIR) part of the electromagnetic spectrum. These materials can be used to fabricate solar cells, photovoltaics, sensors and other devices that absorb or product light in the NIR part of the spectrum. The present invention builds on work with dipryidylmethene (DIPYR) dyes (Golden, et al. J. Org. Chem. 2017, 82(14), 7215-7222). By coupling two DIPYRs together to form a five membered ring system, the absorbance and emission can be shifted into the NIR part of the spectrum. A modeling study is presented below, using models that proved to have good correlation with experimental values in previous work. This modeling study shows that the fused DIPYR systems are expected to substantial absorption and emission in the NIR part of the spectrum. These compounds have applicability in photovoltaic devices.

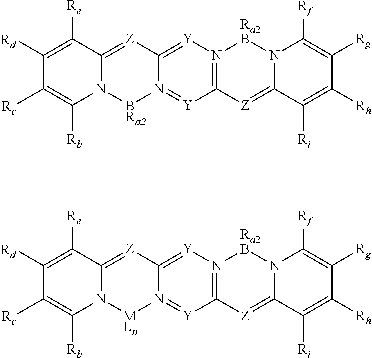

with Ra=F, halide, alkoxide, alkyl, aryl
R_{b}-Ri=H, halide, alkoxide, alkyl, aryl and can be formed into one more more fused rings
Y═CH, C-alkyl, C-aryl, N, C—CN
Z═CH, C-alkyl, C-aryl, N, C-donor, C-acceptor
MLₙ=a diamagnetic nonvalent, divalent or trivalent metal center, with the metal chosen from either the transition metals or the main group metals

The calculations given in the table are for the structures shown below.

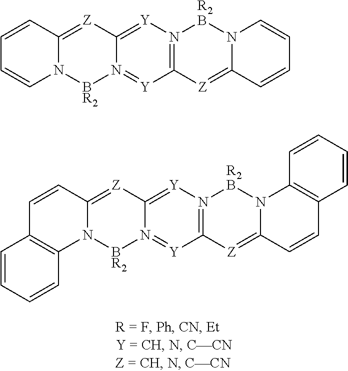

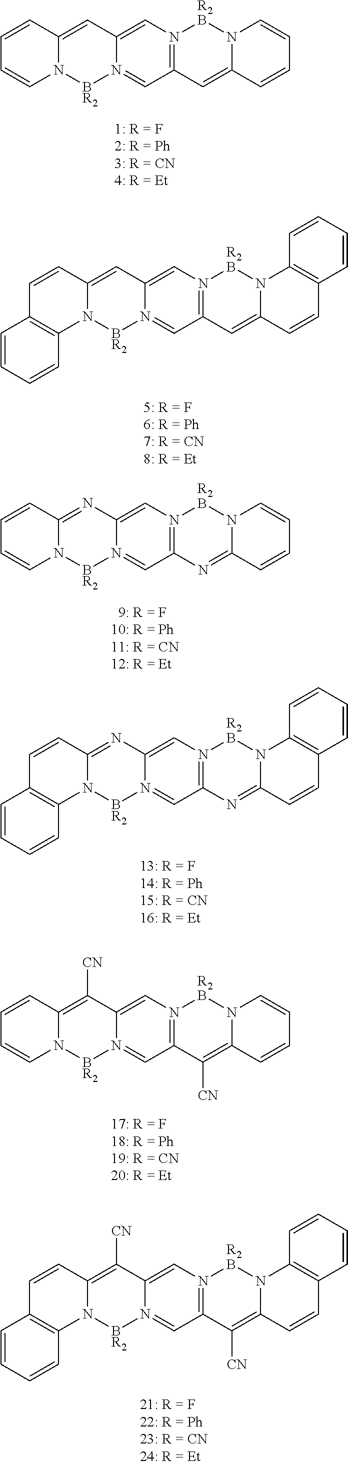

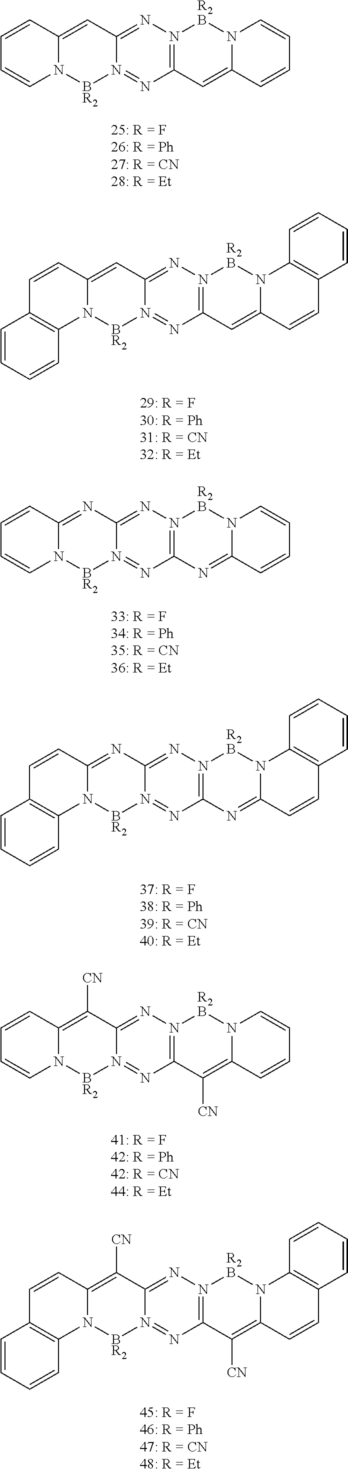

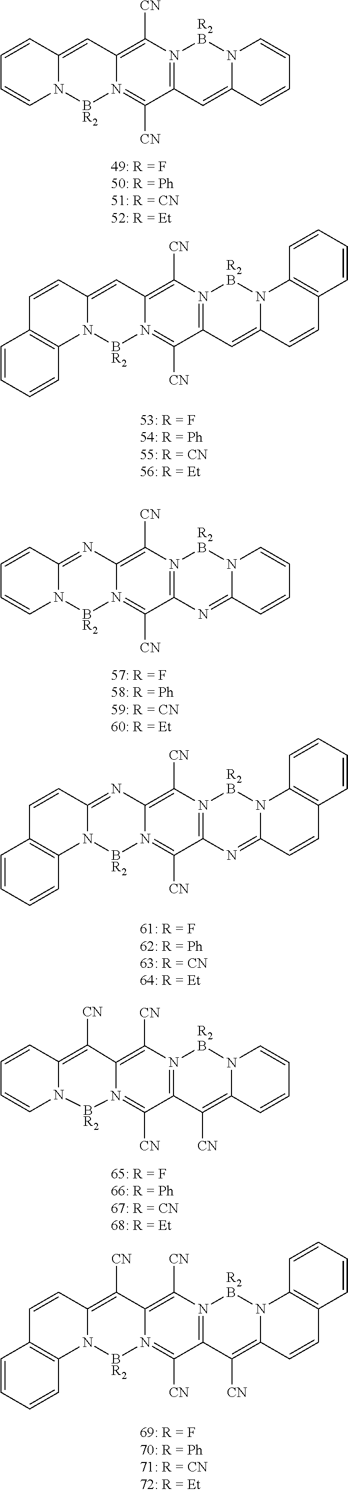

Calculations were completed for the pyrazine set of molecules. HOMO is the energy of the highest occupied molecular orbital, LUMO is the energy of the lowest unoccupied molecular orbital, S₁ is the energy of the lowest energy singlet excited state (a good estimate of the absorbance energy), ƒ is the oscillator strength of the transition, S₂ is the energy of the first singlet higher in energy than S₁, T₁ and T₂ correspond to the energies of the two lowest energy triplet states.

The tetrazine and 3,6-CN pyrazine derivatives are expected to follow the same trends when permutating F, Ph, CN and Et.

It is clear from table that the fused DIPYR complexes have NIR absorbance and expected to have emission in the NIR. The oscillator strengths for the S₁ transitions are good, suggesting that these materials will be strong absorbers. The emission efficiency is not easy to estimate since multiple nonradiative pathways may limit the efficiency, but the fluorescence is expected to come near the absorbance energy.

TD-DFT B3LYP/6-31G** (0.44 eV correction for S₁ state applied, see Golden, et al. J. Org. Chem. 2017, 82(14), 7215-7222)

| | HOMO | LUMO | | | T₁ | T₂ |
|---|---|---|---|---|---|---|
| | (eV) | (eV) | S₁/f | S₂/f | (eV) | (eV) |
| 1 | −4.68 | −2.78 | 1.17 eV | 2.55 eV | 0.69 | 1.68 |
| | | | (1059 nm)/0.13 | (486 nm)/0.61 | | |
| 2 | −4.13 | −2.25 | 1.08 eV | 2.47 eV | 0.68 | 1.67 |
| | | | (1148 eV)/0.10 | (502 nm)/0.48 | | |
| 3 | −5.07 | −3.36 | 0.95 eV | 2.49 eV | 0.44 | 1.64 |
| | | | (1305 nm)/0.11 | (498 nm)/0.60 | | |
| 4 | −3.98 | −2.16 | 0.99 eV | 2.40 eV | 0.62 | 1.61 |
| | | | (1252 nm)/0.09 | (517 nm)/0.40 | | |
| 5 | −4.87 | −2.94 | 1.17 eV | 2.42 eV | 0.78 | 1.60 |
| | | | (1059 nm)/0.23 | (512 nm)/0.99 | | |
| 6 | −4.30 | −2.43 | 1.07 eV | 2.31 eV | 0.76 | 1.55 |
| | | | (1156 nm)/0.18 | (537 nm)/0.77 | | |
| 7 | −5.17 | −3.45 | 0.96 eV | 2.36 eV | 0.54 | 1.54 |
| | | | (1292 nm)/0.16 | (525 nm)/1.03 | | |
| 8 | −4.21 | −2.39 | 0.99 eV | 2.26 eV | 0.71 | 1.50 |
| | | | (1252 nm)/0.16 | (548 nm)/0.73 | | |
| 9 | −5.20 | −2.72 | 1.71 eV | 3.07 eV | 1.12 | 2.22 |
| | | | (725 nm)/0.19 | (404 nm)/0.66 | | |
| 10 | −4.81 | −2.39 | 1.60 eV | 2.93 eV | 1.16 | 2.16 |
| | | | (773 nm)/0.14 | (423 nm)/0.47 | | |
| 11 | −5.85 | −3.60 | 1.49 eV | 2.95 eV | 0.91 | 2.12 |
| | | | (832 nm)/0.16 | (420 nm)/0.67 | | |
| 12 | −4.69 | −2.30 | 1.54 eV | 2.89 eV | 1.13 | 2.12 |
| | | | (805 nm)/0.13 | (429 nm)/0.40 | | |
| 13 | −5.31 | −2.80 | 1.71 eV | 2.89 eV | 1.23 | 2.11 |
| | | | (725 nm)/0.34 | (430 nm)/0.86 | | |
| 14 | −4.93 | −2.52 | 1.58 eV | 2.76 eV | 1.23 | 2.02 |
| | | | (785 nm)/0.27 | (449 nm)/0.67 | | |
| 15 | −5.87 | −3.59 | 1.51 eV | 2.80 eV | 1.03 | 2.04 |
| | | | (821 nm)/0.28 | (443 nm)/0.90 | | |
| 16 | −4.87 | −2.47 | 1.52 eV | 2.73 eV | 1.22 | 1.99 |
| | | | (815 nm)/0.24 | (454 nm)/0.62 | | |
| 17 | −5.27 | −3.16 | 1.33 eV | 2.71 eV | 0.93 | 1.98 |
| | | | (934 nm)/0.15 | (457 nm)/0.57 | | |
| 18 | −4.86 | −2.81 | 1.20 eV | 2.58 eV | 0.91 | 1.93 |
| | | | (1033 nm)/0.11 | (481 nm)/0.43 | | |
| 19 | −5.83 | −4.02 | 1.02 eV | 2.46 eV | 0.61 | 1.84 |
| | | | (1216 nm)/0.11 | (504 nm)/0.00 | | |
| 20 | −4.84 | −2.79 | 1.18 eV | 2.55 eV | 0.92 | 1.93 |
| | | | (1051 nm)/0.10 | (486 nm)/0.00 | | |
| 21 | −5.33 | −3.24 | 1.28 eV | 2.56 eV | 0.97 | 1.86 |
| | | | (969 nm)/0.22 | (484 nm)/0.86 | | |
| 22 | −4.96 | −2.88 | 1.22 eV | 2.46 eV | 1.01 | 1.82 |
| | | | (1016 nm)/0.19 | (504 nm)/0.61 | | |
| 23 | −5.82 | −3.96 | 1.06 eV | 2.40 eV | 0.74 | 1.77 |
| | | | (1170 nm)/0.18 | (517 nm)/0.00 | | |
| 24 | −4.95 | −2.90 | 1.16 eV | 2.42 eV | 0.98 | 1.79 |
| | | | (1069 nm)/0.17 | (512 nm)/0.59 | | |
| 25 | −4.84 | −3.64 | 0.56 eV | 1.92 eV | 0.02 | 1.46 |
| | | | (2216 nm)/0.04 | (646 nm)/0.00 | | |
| 26 | −4.49 | −3.13 | 0.66 eV | 2.02 eV | 0.21 | 1.65 |
| | | | (1409 nm)/0.03 | (614 nm)/0.00 | | |
| 27 | | | | | | |
| 28 | | | | | | |
| 29 | −4.96 | −3.70 | 0.57 eV | 1.85 eV | 0.13 | 1.43 |
| | | | (2175 nm)/0.04 | (670 nm)/0.00 | | |
| 30 | −4.63 | −3.31 | 0.56 eV | 1.80 eV | 0.23 | 1.49 |
| | | | (2214 nm)/0.02 | (689 nm)/0.00 | | |
| 31 | | | | | | |
| 32 | | | | | | |
| 33 | −5.49 | −3.59 | 1.05 eV | 2.52 eV | 0.16 | 2.01 |
| | | | (1181 nm)/0.02 | (492 nm)/0.00 | | |
| 34 | −5.27 | −3.34 | 1.24 eV | 2.30 eV | 0.70 | 2.04 |
| | | | (1000 nm)/0.04 | (539 nm)/0.03 | | |
| 35 | | | | | | |
| 36 | | | | | | |
| 37 | −5.57 | −3.64 | 1.06 eV | 2.44 eV | 0.39 | 2.00 |
| | | | (1170 nm)/0.03 | (508 nm)/0.00 | | |
| 38 | −5.35 | −3.42 | 1.19 eV | 2.12 eV | 0.75 | 1.94 |
| | | | (1042 nm)/0.03 | (585 nm)/0.01 | | |
| 39 | | | | | | |
| 40 | | | | | | |
| 41 | −5.65 | −4.32 | 0.62 eV | 1.86 eV | 0.22 | 1.44 |
| | | | (2000 nm)/0.04 | (667 nm)/0.00 | | |
| 42 | −5.20 | −3.70 | 0.74 eV | 1.97 eV | 0.39 | 1.65 |
| | | | (1675 nm)/0.03 | (629 nm)/0.00 | | |
| 43 | | | | | | |
| 44 | | | | | | |
| 45 | −5.64 | −4.35 | 0.55 eV | 1.72 eV | 0.22 | 1.35 |
| | | | (2254 nm)/0.03 | (721 nm)/0.00 | | |
| 46 | −5.27 | −3.88 | 0.57 eV | 1.64 eV | 0.35 | 1.38 |
| | | | (2175 nm)/0.02 | (756 nm)/0.00 | | |
| 47 | | | | | | |
| 48 | | | | | | |
| 49 | −4.95 | −3.70 | 0.66 eV | 2.04 eV | 0.19 | 1.68 |
| | | | (1879 nm)/0.06 | (608 nm)/0.00 | | |
| 50 | −4.52 | −3.36 | 0.52 eV | 1.89 eV | 0.12 | 1.52 |
| | | | (2384 nm)/0.05 | (656 nm)/0.00 | | |
| 51 | | | | | | |
| 52 | | | | | | |
| 53 | −5.04 | −3.77 | 0.63 eV | 1.93 eV | 0.25 | 1.56 |
| | | | (1968 nm)/0.05 | (642 nm)/0.00 | | |
| 54 | −4.65 | −3.44 | 0.52 eV | 1.78 eV | 0.21 | 1.41 |
| | | | (2384 nm)/0.03 | (697 nm)/0.00 | | |
| 55 | | | | | | |
| 56 | | | | | | |
| 57 | −5.71 | −3.83 | 1.11 eV | 2.63 eV | 0.52 | 2.14 |
| | | | (1117 nm)/0.06 | (471 nm)/0.00 | | |
| 58 | −5.24 | −3.43 | 0.99 eV | 2.37 eV | 0.50 | 1.98 |
| | | | (1252 nm)/0.04 | (523 nm)/0.00 | | |
| 59 | | | | | | |
| 60 | | | | | | |
| 61 | −5.75 | −3.86 | 1.09 eV | 2.42 eV | 0.60 | 2.04 |
| | | | (1138 nm)/0.05 | (512 nm)/0.00 | | |
| 62 | −5.31 | −3.48 | 1.19 eV | 2.24 eV | 0.75 | 1.96 |
| | | | (1042 nm)/0.07 | (554 nm)/0.00 | | |
| 63 | | | | | | |
| 64 | | | | | | |
| 65 | −5.71 | −3.95 | 0.94 eV | 2.38 eV | 0.48 | 1.61 |
| | | | (1319 nm)/0.03 | (521 nm)/0.00 | | |
| 66 | −5.27 | −3.59 | 0.97 eV | 2.17 eV | 0.62 | 1.62 |
| | | | 0(1278 nm)/.05 | (571 nm)/0.00 | | |
| 67 | | | | | | |
| 68 | | | | | | |
| 69 | −5.71 | −4.09 | 0.74 eV | 2.01 eV | 0.45 | 1.64 |
| | | | (1675 nm)/0.02 | (617 nm)/0.00 | | |
| 70 | −5.32 | −3.68 | 0.87 eV | 1.94 eV | 0.63 | 1.60 |
| | | | (1425 nm)/0.02 | (639 nm)/0.00 | | |
| 71 | | | | | | |
| 72 | | | | | | |

NIR-Absorbing DIPYRs: Experimental and Expected Procedures

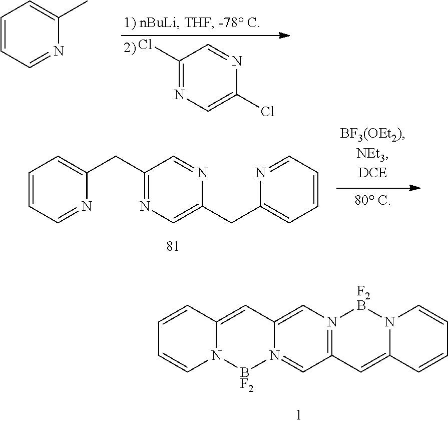

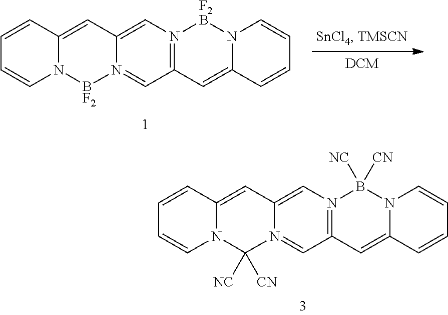

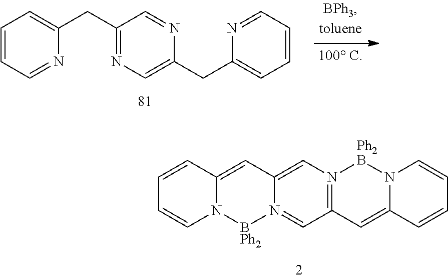

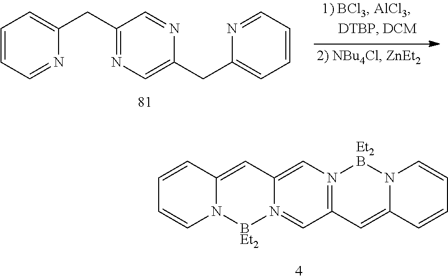

2,5-Bis(pyridine-2-ylmethyl)pyrazine (81):

2-Methylpyridine (8 Eq.) is dissolved in dry, degassed THF under a nitrogen atmosphere. The resulting solution is cooled to −78° C. and n-butyl lithium solution (8 Eq.) is added dropwise over a period of 30 min and the resulting suspension is stirred for 45 min at −78° C. The cooling bath is removed and the suspension is stirred for 30 min at ambient temperature. The solution is then cooled to −20° C. and 2,5-dichloropyrazine (1 Eq.) is added. The solution is then refluxed for 4 h and stirred at room temperature for another 16 h. Saturated NH₄Cl solution is then added and the aqueous phase is extracted with ethyl acetate. The combined organic phases are then washed with brine, dried over sodium sulfate, filtered and the solvent is removed in vacuo. Remaining 2-methylpyridine is removed by vacuum distillation. The residue is then purified by flash column chromatography on basic alumina to yield 81.

Pyridine-Pyrazine DIPYR (1):

81 (1 Eq.) is dissolved in dry, degassed dichloroethane under a nitrogen atmosphere, triethylamine (10 Eq.) is added and the resulting solution is stirred for 15 min at room temperature. Boron trifluoride diethyl etherate (10 Eq.) is added dropwise and the solution is stirred at 80° C. for 72 h. After cooling to room temperature, saturated aqueous NaHCO₃ solution is added. After separating the organic phase, the aqueous phase is extracted with dichloromethane. The combined organic phases are dried over sodium sulfate, filtered and the solvent is removed in vacuo. The residue is then purified by flash column chromatography to yield 1.

Pyridine-Pyrazine BPh2-DIPYR (2):

81 (1 Eq.) is dissolved in dry, degassed toluene under a nitrogen atmosphere, triphenylborane (4 Eq.) is added and the resulting solution is stirred at reflux for 72 h. After cooling to room temperature, saturated aqueous NaHCO₃ solution is added. After separating the organic phase, the aqueous phase is extracted with ethyl acetate. The combined organic phases are dried over sodium sulfate, filtered and the solvent is removed in vacuo. The residue is then purified by flash column chromatography to yield 2.

Pyridine-Pyrazine BCN2-DIPYR (3):

To a solution of 1 (1 Eq.) in dry dichloromethane under nitrogen is added a solution of tin tetrachloride in dichloromethane (1 Eq.) dropwise followed by trimethylsilyl cyanide (14 Eq.). After stirring for 10 min at room temperature, water is added and the aqueous phase is extracted with dichloromethane. The combined organic phases are washed with sodium bicarbonate solution, dried over sodium sulfate, filtered, and the solvent is removed in vacuo. The residue is purified by flash column chromatography to yield 3.

Pyridine-Pyrazine BEt2-DIPYR (4):

To a solution of 81 (1 Eq.) in dry dichloromethane under a nitrogen atmosphere is added boron trichloride in hexane (4 Eq.), aluminum chloride (4 Eq.) and 2,6-di-teat-butyl pyridine (2 Eq.) and the mixture is stirred at room temperature for 16 h. Tetrabutylammonium chloride (2 Eq.) is added followed by diethyl zinc (5 Eq.). The mixture is stirred for 16 h at room temperature and is then poured onto ice. The phases are separated and the aqueous phase is extracted with dichloromethane. The combined organic phases are dried over sodium sulfate, filtered and the solvent is removed in vacuo. The residue is purified by flash column chromatography to yield 4.

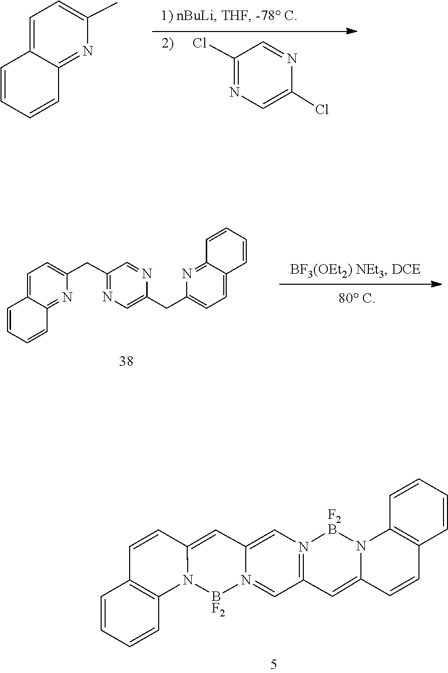

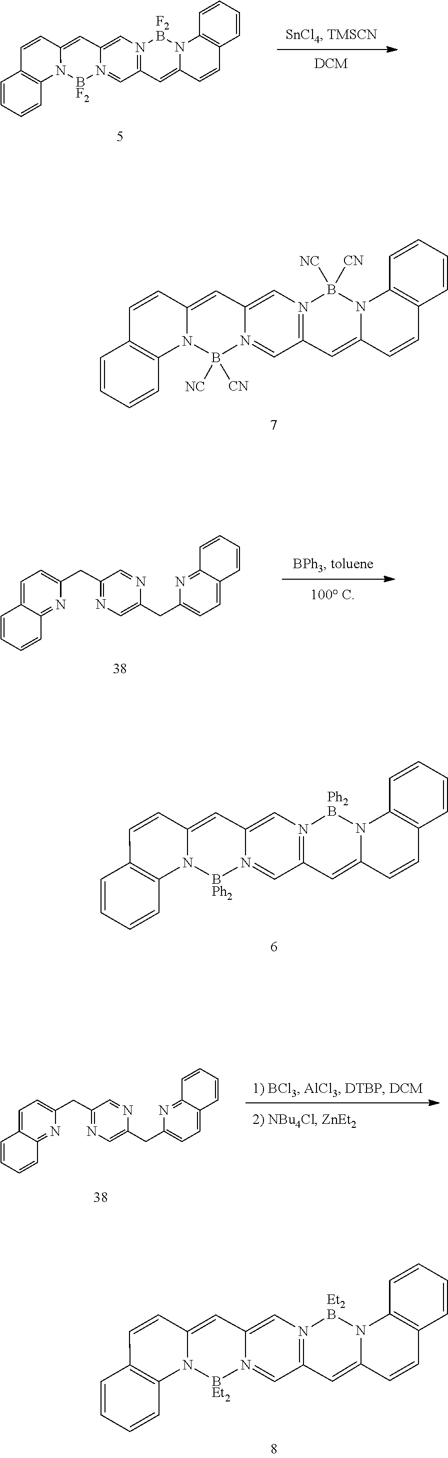

2,5-Bis(quinoline-2-ylmethyl)pyrazine (82):

2-Methylquinoline (8 Eq.) is dissolved in dry, degassed THF under a nitrogen atmosphere. The resulting solution is cooled to −78° C. and n-butyl lithium solution (8 Eq.) is added dropwise over a period of 30 min and the resulting suspension is stirred for 45 min at −78° C. The cooling bath is removed and the suspension is stirred for 30 min at ambient temperature. The solution is then cooled to −20° C. and 2,5-dichloropyrazine (1 Eq.) is added. The solution is then refluxed for 4 h and stirred at room temperature for another 16 h. Saturated NH₄Cl solution is then added and the aqueous phase is extracted with ethyl acetate. The combined organic phases are then washed with brine, dried over sodium sulfate, filtered and the solvent is removed in vacuo. Remaining 2-methylquinoline is removed by vacuum distillation. The residue is then purified by flash column chromatography on basic alumina to yield 82.

Quinoline-Pyrazine DIPYR (5):

82 (1 Eq.) is dissolved in dry, degassed dichloroethane under a nitrogen atmosphere, triethylamine (10 Eq.) is added and the resulting solution is stirred for 15 min at room temperature. Boron trifluoride diethyl etherate (10 Eq.) is added dropwise and the solution is stirred at 80° C. for 72 h. After cooling to room temperature, saturated aqueous NaHCO 3 solution is added. After separating the organic phase, the aqueous phase is extracted with dichloromethane. The combined organic phases are dried over sodium sulfate, filtered and the solvent is removed in vacuo. The residue is then purified by flash column chromatography to yield 5.

Quinoline-Pyrazine BPh2-DIPYR (6):

82 (1 Eq.) is dissolved in dry, degassed toluene under a nitrogen atmosphere, triphenylborane (4 Eq.) is added and the resulting solution is stirred at reflux for 72 h. After cooling to room temperature, saturated aqueous NaHCO₃ solution is added. After separating the organic phase, the aqueous phase is extracted with ethyl acetate. The combined organic phases are dried over sodium sulfate, filtered and the solvent is removed in vacuo. The residue is then purified by flash column chromatography to yield 6.

Quinoline-Pyrazine BCN2-DIPYR (7):

To a solution of 5 (1 Eq.) in dry dichloromethane under nitrogen is added a solution of tin tetrachloride in dichloromethane (1 Eq.) dropwise followed by trimethylsilyl cyanide (14 Eq.). After stirring for 10 min at room temperature, water is added and the aqueous phase is extracted with dichloromethane. The combined organic phases are washed with sodium bicarbonate solution, dried over sodium sulfate, filtered, and the solvent is removed in vacuo. The residue is purified by flash column chromatography to yield 7.

Quinoline-Pyrazine BEt2-DIPYR (8):

To a solution of 82 (1 Eq.) in dry dichloromethane under a nitrogen atmosphere is added boron trichloride in hexane (4 Eq.), aluminum chloride (4 Eq.) and 2,6-di-teat-butyl pyridine (2 Eq.) and the mixture is stirred at room temperature for 16 h. Tetrabutylammonium chloride (2 Eq.) is added followed by diethyl zinc (5 Eq.). The mixture is stirred for 16 h at room temperature and is then poured onto ice. The phases are separated and the aqueous phase is extracted with dichloromethane. The combined organic phases are dried over sodium sulfate, filtered and the solvent is removed in vacuo. The residue is purified by flash column chromatography to yield 8.

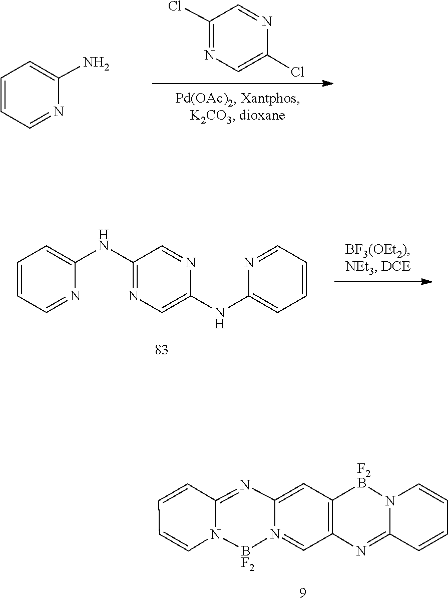

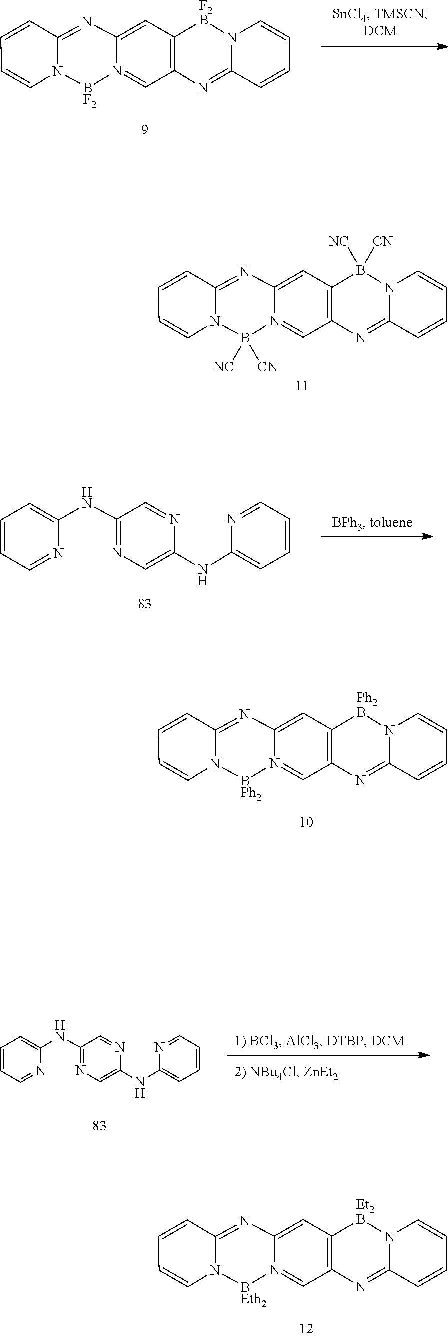

2,5-Bis(pyridyl-2-ylamine)pyrazine (83):

2-Pyridylamine (2.4 Eq.), 2,5-dichloropyrazine (1 Eq.) and potassium carbonate (20 Eq.) are suspended in dry, degassed dioxane under a nitrogen atmosphere. In separate flask, palladium acetate (0.1 Eq.) is added to a solution of Xantphos (0.2 Eq.) in dry, degassed dioxane. After stirring for 15 min at ambient temperature, the latter solution is canula transferred to the former suspension. The resulting suspension is then heated to reflux for 72 h. After cooling to room temperature, the suspension is filtered and the remaining solid washed with water, methanol and dichloromethane. The residue is purified by sublimation to give 83.

Pyridine-Pyrazine aza-DIPYR (9):

83 (1 Eq.) is dissolved in dry, degassed dichloroethane under a nitrogen atmosphere, triethylamine (10 Eq.) is added and the resulting solution is stirred for 15 min at room temperature. Boron trifluoride diethyl etherate (10 Eq.) is added dropwise and the solution is stirred at 80° C. for 72 h. After cooling to room temperature, saturated aqueous NaHCO₃ solution is added. After separating the organic phase, the aqueous phase is extracted with dichloromethane. The combined organic phases are dried over sodium sulfate, filtered and the solvent is removed in vacuo. The residue is then purified by flash column chromatography to yield 9.

Pyridine-Pyrazine BPh2-aza-DIPYR (10):

83 (1 Eq.) is dissolved in dry, degassed toluene under a nitrogen atmosphere, triphenylborane (4 Eq.) is added and the resulting solution is stirred at reflux for 72 h. After cooling to room temperature, saturated aqueous NaHCO₃ solution is added. After separating the organic phase, the aqueous phase is extracted with ethyl acetate. The combined organic phases are dried over sodium sulfate, filtered and the solvent is removed in vacuo. The residue is then purified by flash column chromatography to yield 10.

Pyridine-Pyrazine BCN2-aza-DIPYR (11):

To a solution of 9 (1 Eq.) in dry dichloromethane under nitrogen is added a solution of tin tetrachloride in dichloromethane (1 Eq.) dropwise followed by trimethylsilyl cyanide (14 Eq.). After stirring for 10 min at room temperature, water is added and the aqueous phase is extracted with dichloromethane. The combined organic phases are washed with sodium bicarbonate solution, dried over sodium sulfate, filtered, and the solvent is removed in vacuo. The residue is purified by flash column chromatography to yield 11.

Pyridine-Pyrazine BEt2-aza-DIPYR (12):

To a solution of 83 (1 Eq.) in dry dichloromethane under a nitrogen atmosphere is added boron trichloride in hexane (4 Eq.), aluminum chloride (4 Eq.) and 2,6-di-teat-butyl pyridine (2 Eq.) and the mixture is stirred at room temperature for 16 h. Tetrabutylammonium chloride (2 Eq.) is added followed by diethyl zinc (5 Eq.). The mixture is stirred for 16 h at room temperature and is then poured onto ice. The phases are separated and the aqueous phase is extracted with dichloromethane. The combined organic phases are dried over sodium sulfate, filtered and the solvent is removed in vacuo. The residue is purified by flash column chromatography to yield 12.

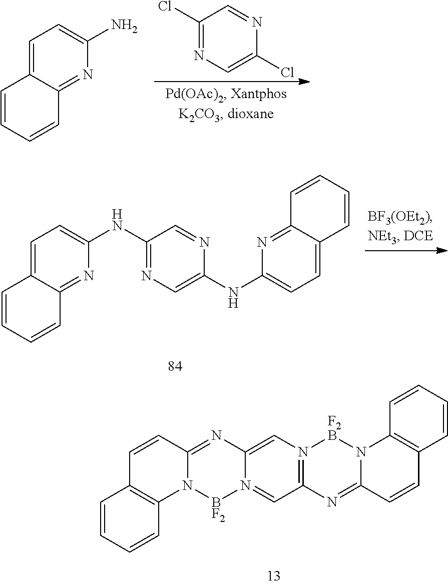

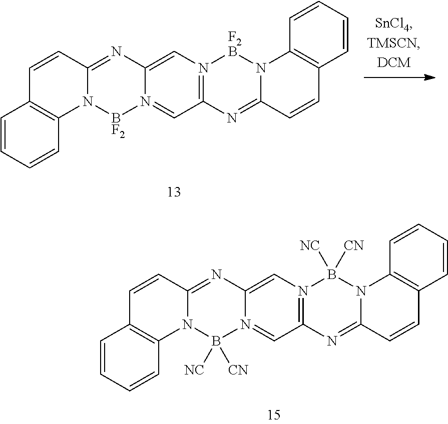

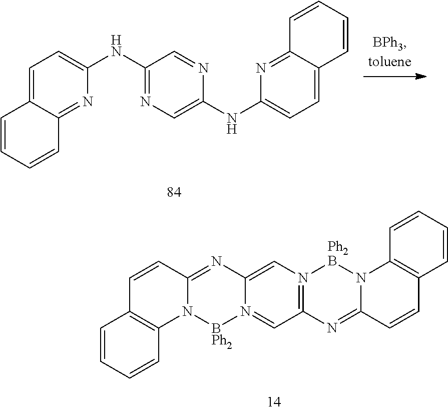

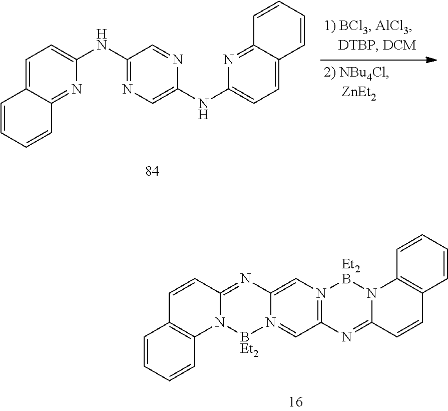

We claim:

1. A compound represented by Formula I: 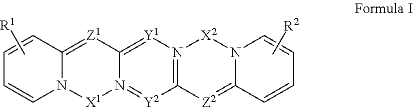
wherein:
X¹, and X² are each independently selected from the group consisting of B(R^{a})₂ and MLₙ;
M is a diamagnetic monovalent, divalent, or trivalent metal center, wherein the metal is a transition metal or a main group metal;
L is a monoanionic ligand; and
n+1 is the oxidation state of the metal;
Y¹ and Y² are each selected from the group consisting of CR³ and N;
Z¹ and Z² are each selected from the group consisting of CR⁴ and N;
R^{a} is selected from the group consisting of halide, alkoxide, alkyl, aryl, nitrile, and combinations thereof;
R¹ and R² each represent mono to the maximum allowable substitution, or no substitution;
each R¹, R², R³, and R⁴, are independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cyano, cycloalkenyl, heteroalkenyl, alkynyl, aryl, heteroaryl, acyl, carboxylic acid, ether, ester, nitro, nitrile, isonitrile, sulfanyl, sulfinyl, sulfonyl, phosphino, and combinations thereof;
any two R¹, R², R³, R⁴, and R^{a} can optionally join to form a carbocyclic ring or a heterocyclic ring, which is optionally substituted.

2. The compound of claim 1, wherein Y¹ and Y² are each N.

3. The compound of claim 1, wherein Z¹ and Z² are each CR⁴.

4. The compound of claim 3, wherein R⁴ is nitrile.

5. The compound of claim 1, wherein X¹ and X² are each B(R^{a})₂.

6. The compound of claim 1, wherein R^{a} is nitrile, phenyl, or ethyl.

7. The compound of claim 1, wherein one of X¹ and X² is B(R^{a})₂ and the other of X¹ and X² is Ir(L)₂;
wherein L represents a bidentate monoanionic ligand; and
each L can be the same or different.

8. The compound of claim 1, wherein X¹ and X² are both Ir(L)₂;
L represents a bidentate monoanionic ligand; and
each L can be the same or different.

9. The compound of claim 8, wherein each L is independently selected from the group consisting of: 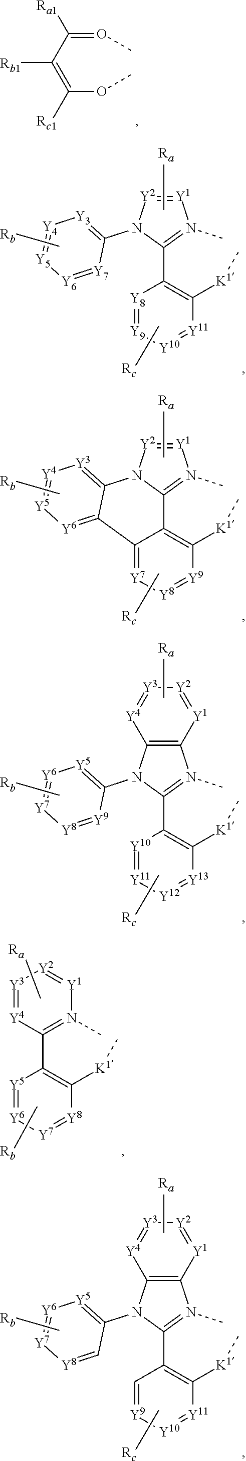 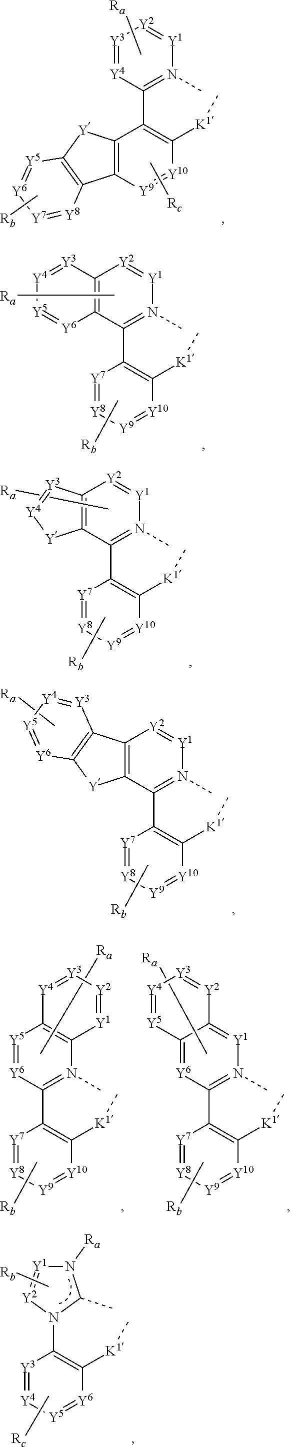 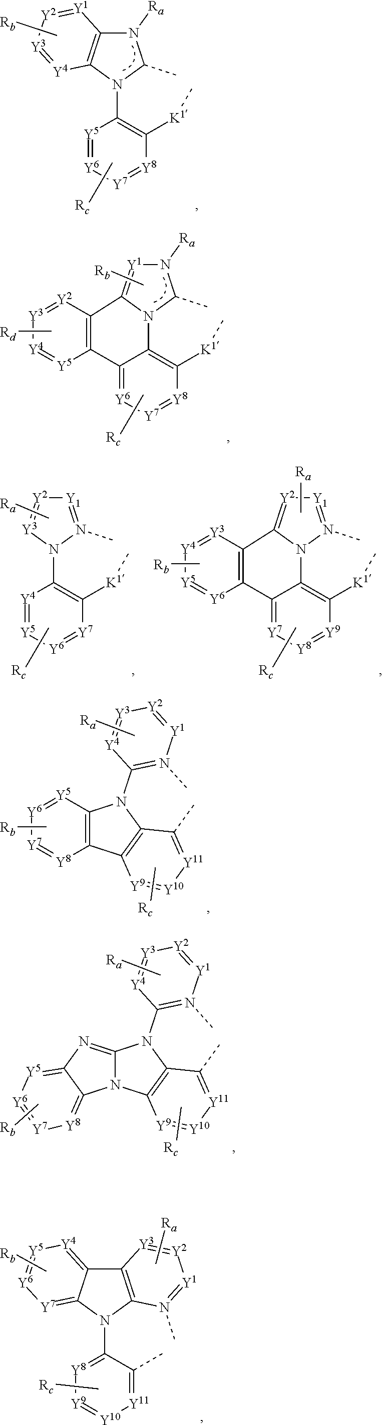 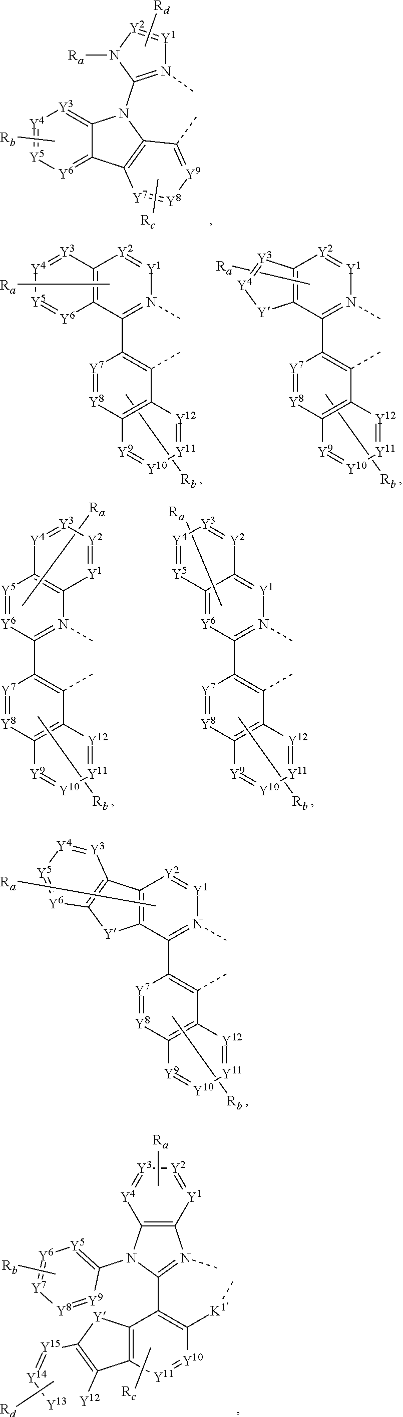 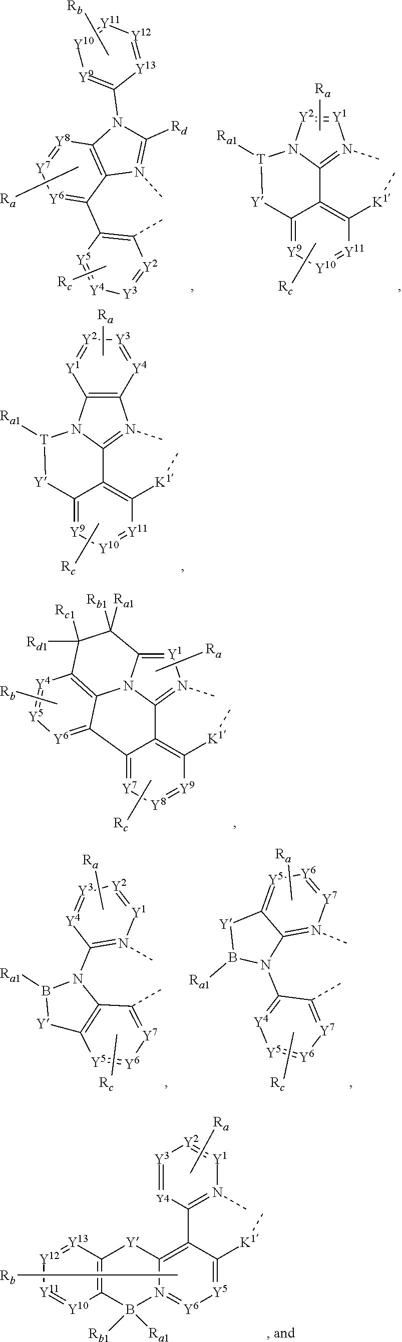 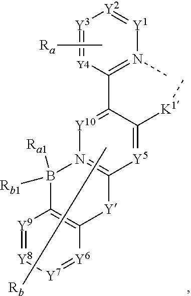
wherein:
T is selected from the group consisting of B, Al, Ga, and In;
K^{1′} is selected from the group consisting of a single bond, O, S, NRₑ, PRₑ, BRₑ, CRₑR_{f}, and SiRₑR_{f};
each of Y¹ to Y¹³ is independently selected from the group consisting of C and N;
Y′ is selected from the group consisting of BRₑ, BRₑR_{f}, NRₑ, PRₑ, P(O)Rₑ, O, S, Se, C═O, C═S, C═Se, C═NRₑ, C═CRₑR_{f}, S═O, SO₂, CRₑR_{f}, SiRₑR_{f}, and GeRₑR_{f};
Rₑ and R_{f} can be fused or joined to form a ring;
each Rₐ, R_{b}, R_{c}, and R_{d} independently represents from mono to the maximum allowed number of substitutions, or no substitution;
each of Rₐ₁, R_{b1}, R_{c1}, Rₐ₁, Rₐ, R_{b}, R_{c}, R_{d}, Rₑ, and R_{f} is independently a hydrogen or a subsituent selected from the group consisting of deuterium, halide, alkyl, cycloalkyl, heteroalkyl, arylalkyl, alkoxy, aryloxy, amino, silyl, germyl, boryl, alkenyl, cycloalkenyl, heteroalkenyl, alkynyl, aryl, heteroaryl, acyl, carbonyl, carboxylic acid, ester, nitrile, isonitrile, sulfanyl, selenyl, sulfinyl, sulfonyl, phosphino, and combinations thereof; and
any two substituents of Rₐ₁, R_{b1}, Rₑ₁, Rₐ₁, Rₐ, R_{b}, R_{c}, and R_{d} can be fused or joined to form a ring or form a multidentate ligand

10. The compound of claim 1, wherein the compound is represented by one of the following structures:

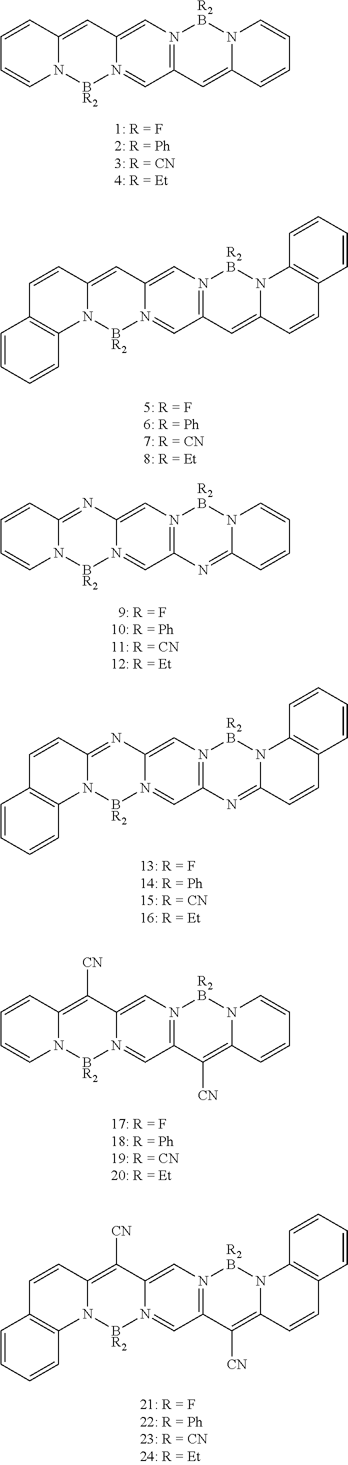

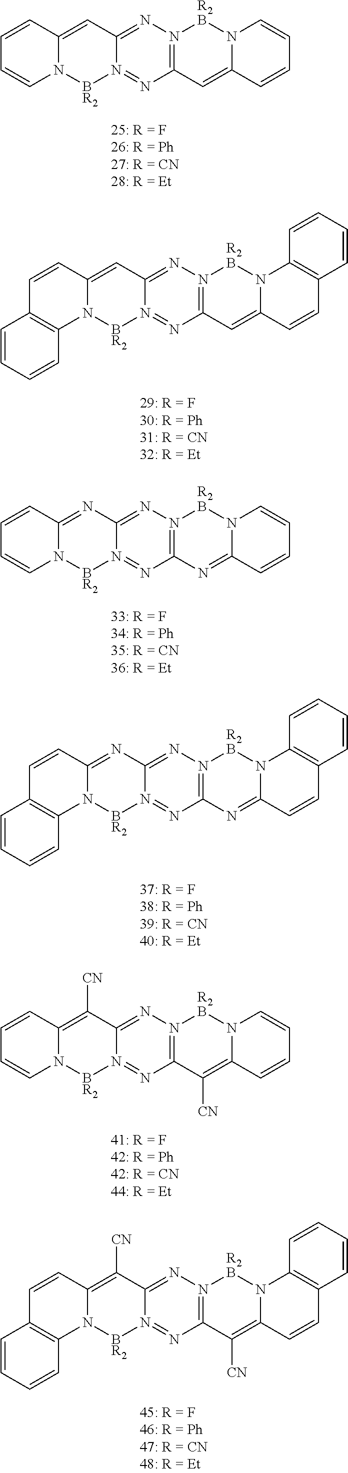

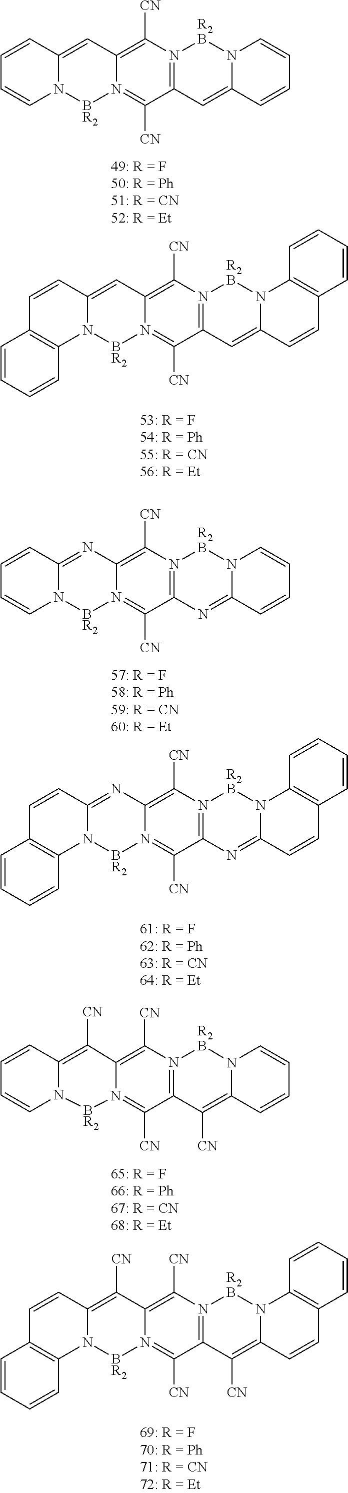

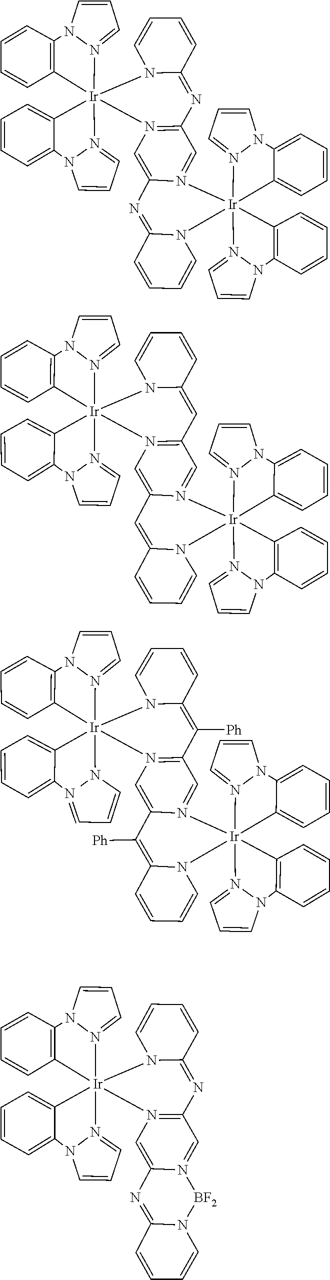

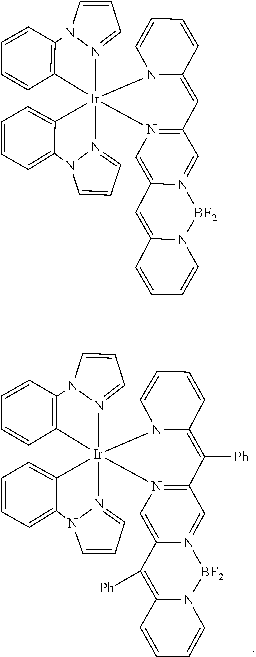

11. A compound of Formula II 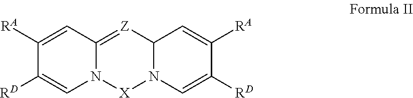
wherein
X is selected from the group consisting of B(R^{a})₂ and MLₙ;
M is a diamagnetic monovalent, divalent, or trivalent metal center, wherein the metal is a transition metal or a main group metal;
L is a monoanionic ligand; and
n+1 is the oxidation state of the metal;
R^{a} is selected from the group consisting of halide, alkoxide, alkyl, aryl, nitrile, and combinations thereof;
Z is selected from the group consisting of CR and N;
each R^{A} is independently an electron-accepting group selected from the group consisting of halogen, nitrile, heteroaryl, and nitro;
each R^{D} is independently an electron-donating group selected from the group consisting of dialkylamino, diarylamino, alkylarylamino, cycloalkylamino, alkyl, aryl, alkoxy, thioalkyl, halogen, and combinations thereof;
R is hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cyano, cycloalkenyl, heteroalkenyl, alkynyl, aryl, heteroaryl, acyl, carboxylic acid, ether, ester, nitro, nitrile, isonitrile, sulfanyl, sulfinyl, sulfonyl, phosphino, and combinations thereof.

12. The compound of claim 11, wherein X is B(Rₐ)₂.

13. The compound of claim 11, wherein each R^{A} represents nitro.

14. The compound of claim 11, wherein each R^{D} represents dialkylamino or cycloalkylamino.

15. The compound of claim 11, wherein the compound is represented by one of the following structures:

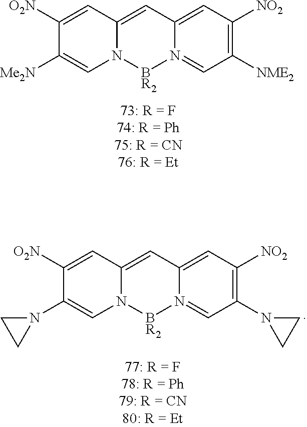

16. An optoelectronic device comprising a compound represented by Formula I 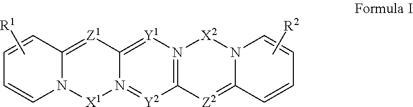
wherein:
X¹, and X² are each independently selected from the group consisting of B(R^{a})₂ and MLₙ;
M is a diamagnetic monovalent, divalent, or trivalent metal center, wherein the metal is a transition metal or a main group metal;
L is a monoanionic ligand; and
n+1 is the oxidation state of the metal;
Y¹ and Y² are each selected from the group consisting of CR³ and N;
Z¹ and Z² are each selected from the group consisting of CR⁴ and N;
R^{a} is selected from the group consisting of halide, alkoxide, alkyl, aryl, nitrile, and combinations thereof;
R¹ and R² each represent mono to the maximum allowable substitution, or no substitution;
each R¹, R², R³, and R⁴, are independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cyano, cycloalkenyl, heteroalkenyl, alkynyl, aryl, heteroaryl, acyl, carboxylic acid, ether, ester, nitro, nitrile, isonitrile, sulfanyl, sulfinyl, sulfonyl, phosphino, and combinations thereof;
any two R¹, R², R³, R⁴, and R^{a} can optionally join to form a carbocyclic ring or a heterocyclic ring, which is optionally substituted.

17. The optoelectronic device of claim 16, wherein the optoelectronic device is selected from the group consisting of an organic light-emitting device (OLED), organic phototransistor, organic photovoltaic cell, and organic photodetector.

18. The optoelectronic device of claim 16, wherein the optoelectronic device is an organic photovoltaic cell.

19. An optoelectronic device comprising the compound of claim 11.

20. The optoelectronic device of claim 19, wherein the optoelectronic device is selected from the group consisting of an organic light-emitting device (OLED), organic phototransistor, organic photovoltaic cell, and organic photodetector.
